(19) United States
(12) Patent Application Publication
(10) Pub. No.: US 2025/0113565 A1
(43) Pub. Date: Apr. 3, 2025

(54) SEMICONDUCTOR DEVICES WITH BACKSIDE SOURCE/DRAIN CONTACTS AND METHODS OF FABRICATION THEREOF

(71) Applicant: TAIWAN SEMICONDUCTOR MANUFACTURING COMPANY, LTD., Hsinchu (TW)

(72) Inventors: Lo-Heng CHANG, Hsinchu (TW); Huan-Chieh SU, Changhua (TW); Chun-Yuan CHEN, Hsinchu (TW); Sheng-Tsung WANG, Hsinchu (TW); Kuo-Cheng CHIANG, Hsinchu (TW); Chih-Hao WANG, Hsinchu (TW)

(21) Appl. No.: 18/431,583

(22) Filed: Feb. 2, 2024

Related U.S. Application Data
(60) Provisional application No. 63/541,950, filed on Oct. 2, 2023.

(51) Int. Cl. H01L 29/06; H01L 21/8234; H01L 27/088; H01L 29/08; H01L 29/423; H01L 29/66; H01L 29/775; H01L 29/786

(52) U.S. Cl. CPC H10D 62/121; H10D 30/014; H10D 30/43; H10D 30/6735; H10D 30/6757; H10D 62/115; H10D 62/151; H10D 64/017; H10D 64/018; H10D 84/013; H10D 84/0151; H10D 84/038; H10D 84/83

(57) ABSTRACT

Embodiments of the present disclosure provide a semiconductor device with backside source/drain contacts formed using a buried source/drain feature and a semiconductor cap layer formed between the buried source/drain feature and a source/drain region. The buried source/drain feature and the semiconductor cap layer enable self-aligned backside source/drain contact and backside isolation. The semiconductor cap layer functions as an etch stop layer during backside contact formation while enabling source/drain region growth without fabrication penalty, such as voids in the source/drain regions.

### CROSS-REFERENCE TO RELATED APPLICATIONS

This application claims priority to U.S. Provisional Patent Application Ser. No. 63/541,950, filed Oct. 2, 2023, which is incorporated by reference in its entirety.

### BACKGROUND

The semiconductor industry has experienced continuous rapid growth due to constant improvements in the integration density of various electronic components. For the most part, this improvement in integration density has come from repeated reductions in minimum feature size, allowing more components to be integrated into a given chip area. As minimum feature size reduces, metal layer routing in the intermetal connection layers also becomes more complex. Therefore, there is a need to solve the above problems.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart of a method for manufacturing of a semiconductor substrate according to embodiments of the present disclosure.

FIGS. 2-4, 5A-50, 6A-6B, 7-20, and 21A-21B schematically illustrate various stages of manufacturing a semiconductor device according to embodiments of the present disclosure.

FIGS. 22-31 schematically illustrate various semiconductor devices according to embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The foregoing broadly outlines some aspects of embodiments described in this disclosure. While some embodiments described herein are described in the context of nanosheet channel FETs, implementations of some aspects of the present disclosure may be used in other processes and/or in other devices, such as planar FETs, Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In addition, although method embodiments may be described in a particular order, various other method embodiments may be performed in any logical order and may include fewer or more steps than what is described herein. In the present disclosure, a source/drain region refers to a source and/or a drain. A source and a drain are interchangeably used.

The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

An integrated circuit (IC) typically includes a plurality of semiconductor devices, such as field-effect transistors and metal interconnection layers formed on a semiconductor substrate. The interconnection layers, designed to connect the semiconductor devices to power supplies, input/output signals, and to each other, may include signal lines and power rails. As semiconductor device size shrinks, space for metal power rails and signal lines decreases.

Embodiments of the present disclosure provide semiconductor devices having contact features, such as source/drain contacts, formed on a backside of a substrate and methods for fabricating such semiconductor devices. Particularly, embodiments of the present disclosure provide a semiconductor device with backside source/drain contacts formed using a buried source/drain feature and a semiconductor cap layer formed between the buried source/drain feature and a source/drain region. The buried source/drain feature and the semiconductor cap layer enable self-aligned backside source/drain contact and backside isolation. The semiconductor cap layer functions as an etch stop layer during backside contact formation while enabling source/drain region growth without fabrication penalty, such as voids in the source/drain regions.

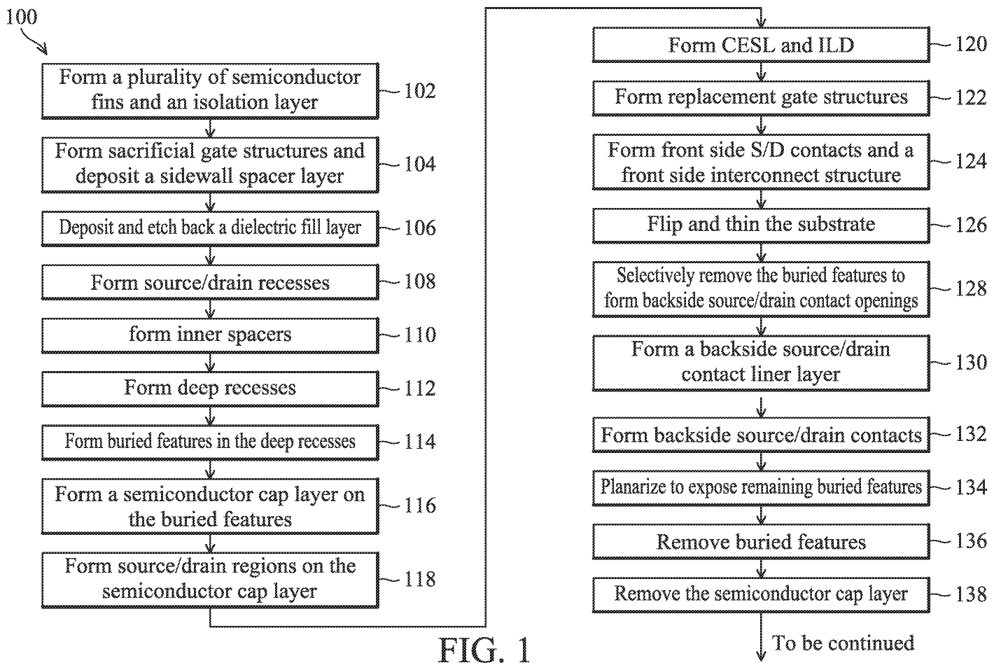

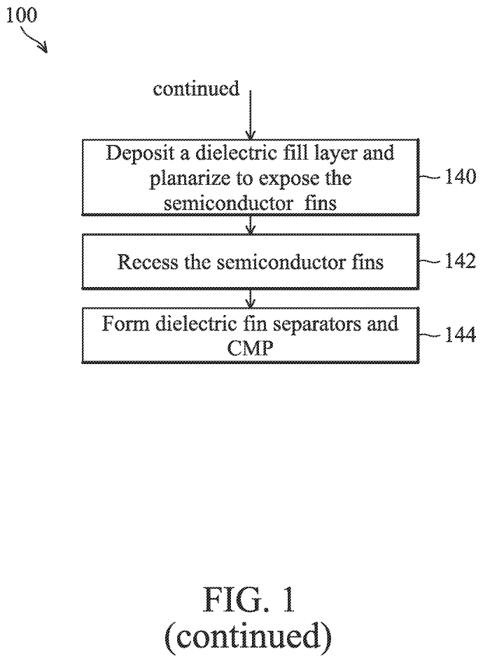

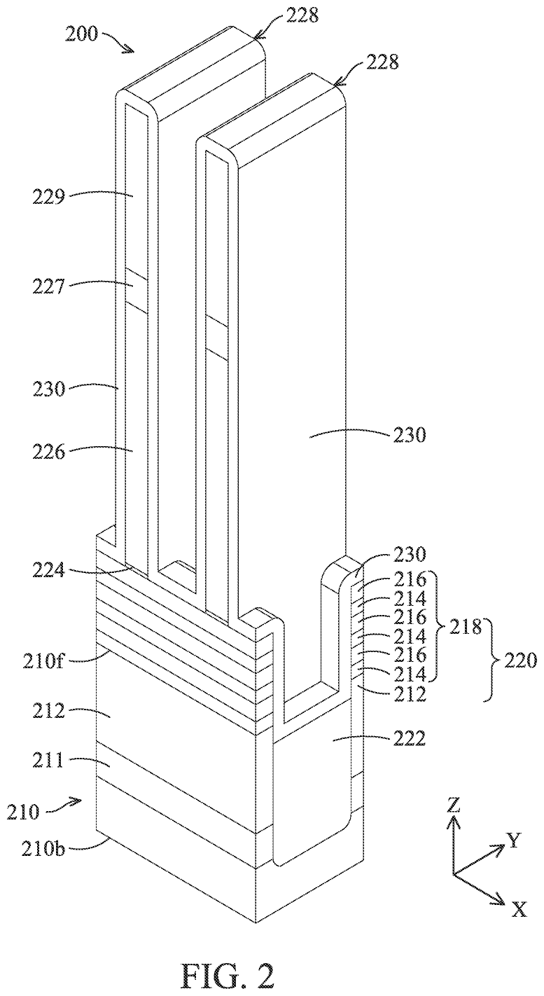

FIG. 1 is a flow chart of a method 100 for manufacturing of a semiconductor substrate according to embodiments of the present disclosure. FIGS. 2-4, 5A-5C, 6A-6B, 7-20, and 21A-21B schematically illustrate various stages of manufacturing a semiconductor device 200 according to the method 100. Additional operations can be provided before, during, and after operations/processes in the method 100, and some of the operations described below can be replaced or eliminated, for additional embodiments of the method. The order of the operations/processes may be interchangeable.

The method 100 begins at operation 102 where a plurality of semiconductor fins 220 are formed over a substrate 210 and an isolation layer 222 is formed in trenches between the plurality of semiconductor fins 220, as shown in FIG. 2. FIG. 2 is a schematic perspective view of the semiconductor device 200 after operation 102.

The substrate 210 is provided to form the semiconductor device 200 thereon. The substrate 210 may include a single crystalline semiconductor material such as, but not limited to Si, Ge, SiGe, GaAs, InSb, GaP, GaSb, InAlAs, InGaAs, GaSbP, GaAsSb, and InP. The substrate 210 may include various doping configurations depending on circuit design. For example, different doping profiles, e.g., n-wells, p-wells, may be formed in the substrate 210 in regions designed for different device types, such as n-type field effect transistors (NFET), and p-type field effect transistors (PFET). In some embodiments, the substrate 210 may be a silicon-on-insulator (SOI) substrate including an insulator structure 211 for enhancement.

The substrate 210 has a top surface 210f and a back surface 210b. A semiconductor stack 218 is then formed over the top surface 210f of the substrate 210. The semiconductor stack 218 includes alternating semiconductor layers made of different materials to facilitate formation of nanosheet channels in a multi-gate device, such as nanosheet channel FETs. In some embodiments, the semiconductor stack 218 includes first semiconductor layers 214 interposed by second semiconductor layers 216. The first semiconductor layers 214 and second semiconductor layers 216 have different oxidation rates and/or etch selectivity.

In later fabrication stages, portions of the second semiconductor layers 216 form nanosheet channels in a multi-gate device. Three first semiconductor layers 214 and three second semiconductor layers 216 are alternately arranged as illustrated in FIG. 2 as an example. More or less semiconductor layers 214 and 216 may be included in the semiconductor stack 218 depending on the desired number of channels in the semiconductor device to be formed. In some embodiments, the number of semiconductor layers 216 is between 1 and 10.

The semiconductor layers 214, 216 may be formed by a molecular beam epitaxy (MBE) process, a metalorganic chemical vapor deposition (MOCVD) process, and/or other suitable epitaxial growth processes. In some embodiments, the semiconductor layers 216 include the same material as the substrate 210. In some embodiments, the semiconductor layers 214 and 216 include different materials than the substrate 210. In some embodiments, the semiconductor layers 214 and 216 are made of materials having different lattice constants. In some embodiments, the first semiconductor layers 214 include an epitaxially grown silicon germanium (SiGe) layer and the second semiconductor layers 216 include an epitaxially grown silicon (Si) layer. Alternatively, in some embodiments, either of the semiconductor layers 214 and 216 may include other materials such as Ge, a compound semiconductor such as SiC, GeAs, GaP, InP, InAs, and/or InSb, an alloy semiconductor such as SiGe, GaAsP, AlInAs, AlGaAs, InGaAs, GaInP, and/or GaInAsP, or combinations thereof.

The first semiconductor layers 214 in channel regions may eventually be removed and serve to define a vertical distance between adjacent channels for a subsequently formed multi-gate device. In some embodiments, the thickness of the first semiconductor layer 214 is equal to or greater than the thickness of the second semiconductor layer 216. In some embodiments, each first semiconductor layer 214 has a thickness in a range between about 5 nm and about 50 nm. In other embodiments, each first semiconductor layer 214 has a thickness in a range between about 10 nm and about 30 nm. In some embodiments, each second semiconductor layer 216 has a thickness in a range between about 5 nm and about 30 nm. In other embodiments, each second semiconductor layer 216 has a thickness in a range between about 10 nm and about 20 nm. In some embodiments, each second semiconductor layer 216 has a thickness in a range between about 6 nm and about 12 nm. In some embodiments, the second semiconductor layers 216 in the semiconductor stack 218 are uniform in thickness.

The semiconductor fins 220 are formed from the semiconductor stack 218 and a portion of the substrate 210. The semiconductor fins 220 may be formed by patterning a hard mask (not shown) formed on the semiconductor stack 218 and one or more etching processes. Each semiconductor fin 220 has a semiconductor stack 218 formed from the semiconductor layers 214, 216 and a well portion 212 formed from the substrate 210. In FIG. 2, the semiconductor fins 220 are formed along the X direction.

The isolation layer 222 is formed in the trenches between the semiconductor fins 220, as shown in FIG. 2. The isolation layer 222 is formed over the substrate 210 to cover the well portion 212 of the semiconductor fins 220. The isolation layer 222 may be formed by a high-density plasma chemical vapor deposition (HDP-CVD), a flowable CVD (FCVD), or other suitable deposition process. In some embodiments, the isolation layer 222 may include silicon oxide, silicon nitride, silicon oxynitride, fluorine-doped silicate glass (FSG), a low-k dielectric, combinations thereof. In some embodiments, the isolation layer 222 is formed to cover the semiconductor fins 220 by a suitable deposition process, such as atomic layer deposition (ALD), and then recess etched using a suitable anisotropic etching process to expose the semiconductor stack 218 of the semiconductor fins 220.

In operation 104, sacrificial gate structures 228 and spacers then formed over the semiconductor fins 220, as shown in FIG. 2. A sacrificial gate dielectric layer 224 is deposited over the exposed surfaces of the semiconductor device 200. The sacrificial gate dielectric layer 224 may be formed conformally over the semiconductor fins 220, and the isolation layer 222. In some embodiments, the sacrificial gate dielectric layer 224 may be deposited by a CVD process, a sub-atmospheric CVD (SACVD) process, a FCVD process, an ALD process, a PVD process, or other suitable process. The sacrificial gate dielectric layer 224 may include one or more layers of dielectric material, such as SiO₂, SiN, a high-K dielectric material, and/or other suitable dielectric material.

A sacrificial gate electrode layer 226 is deposited over the sacrificial gate dielectric layer 224. The sacrificial gate electrode layer 226 may be blanket deposited on the over the sacrificial gate dielectric layer 224. The sacrificial gate electrode layer 226 includes silicon such as polycrystalline silicon or amorphous silicon. The thickness of the sacrificial gate electrode layer is in a range between about 42 nm and about 200 nm. In some embodiments, the sacrificial gate electrode layer 226 is subjected to a planarization operation. The sacrificial gate electrode layer 226 may be deposited using CVD, including LPCVD and PECVD, PVD, ALD, or other suitable process. In some embodiments, a pad layer 227 and a mask layer 229 may be sequentially deposited over the sacrificial gate electrode layer 226. A patterning operation is the performed over the mask layer 229 to form the sacrificial gate structures 228, which cover formed over portions of the semiconductor fins 220 designed to be channel regions.

A gate sidewall spacer layer 230 is then deposited over the semiconductor device 200. The gate sidewall spacer layer 230 may be formed by a blanket deposition of an insulating material followed by anisotropic etch to remove insulating material from horizontal surfaces. The gate sidewall spacer layer 230 may have a thickness in a range between about 2 nm and about 10 nm. In some embodiments, the insulating material of the gate sidewall spacer layer 230 is a silicon nitride-based material, such as SiN, SiON, SiOCN or SiCN and combinations thereof. In other embodiments, the gate sidewall spacer layer 230 may be formed from two or more layers of dielectric materials.

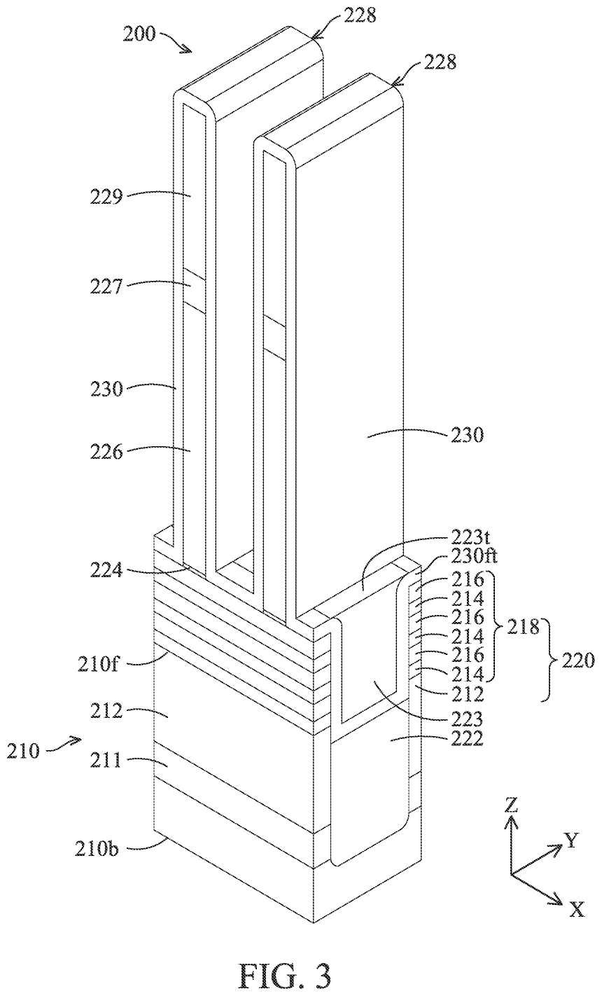

In operation 106, a protective layer 223 is formed around the well portion 212 of the semiconductor fins 220, as shown in FIG. 3, which is a schematic perspective view of the semiconductor device 200. In some embodiments, the protective layer 223 is deposited over the gate sidewall spacer layer 230. After deposition, the fin structures 220 and the sacrificial gate structures 228 are immersed in the protective layer 223. An etch back process is performed to the protective layer 223 so that a top surface 223t is substantially at the same level of a fin top portion 230ft of the gate sidewall spacer layer 230, as shown in FIG. 3.

The protective layer 223 may be selected from materials having etch selectivity with the materials in the gate sidewall spacer layer 230 and the semiconductor fins 220 so that the protective layer 223 may be used to protect underlying structures in the subsequent removal of the gate sidewall spacer layer 230 and the semiconductor fins 220.

In some embodiments, the protective layer 223 may include one or more dielectric material. The protective layer 223 may include silicon oxide, silicon nitride, silicon oxynitride, fluorine-doped silicate glass (FSG), a low-k dielectric, combinations thereof. The protective layer 223 may be formed by a suitable deposition process, for example, by FCVD, HDP-CVD, PVD, ALD, CVD. In some embodiments, the protective layer 223 may include silicon oxide deposited by FCVD.

The protective layer 223 may include other materials, such as metal or metal oxide. In some embodiments, the protective layer 223 may include aluminum, copper, titanium, tantalum, tungsten, cobalt, molybdenum, ruthenium, an alloy thereof, or a combination thereof, which is formed by CVD, ALD, electro-plating, or other suitable method. In other embodiments, the protective layer 223 may include one or more metal oxides, such as HfO₂, HfSiO, HfSiON, HfTaO, HfTIO, HfZrO, zirconium oxide, aluminum oxide, titanium oxide, lanthanum oxide, yttrium oxide, hafnium dioxide-alumina (HfO₂—Al₂O₃) alloy, and/or combinations thereof, which may be formed by CVD, ALD or any suitable method.

The etch back process may be an isotropic etching process such a dry chemical etching or wet etching, or an anisotropic etching process such as dry plasma etching. In some embodiments, a desired thickness of the remaining protective layer 223 may be obtained by adjusting etching time.

After the operation 106, the trenches between the semiconductor fins 220 remain substantially filled by the protective layer 223. The protective layer 223 protects the isolation layer 222 from processing environments during subsequent processing.

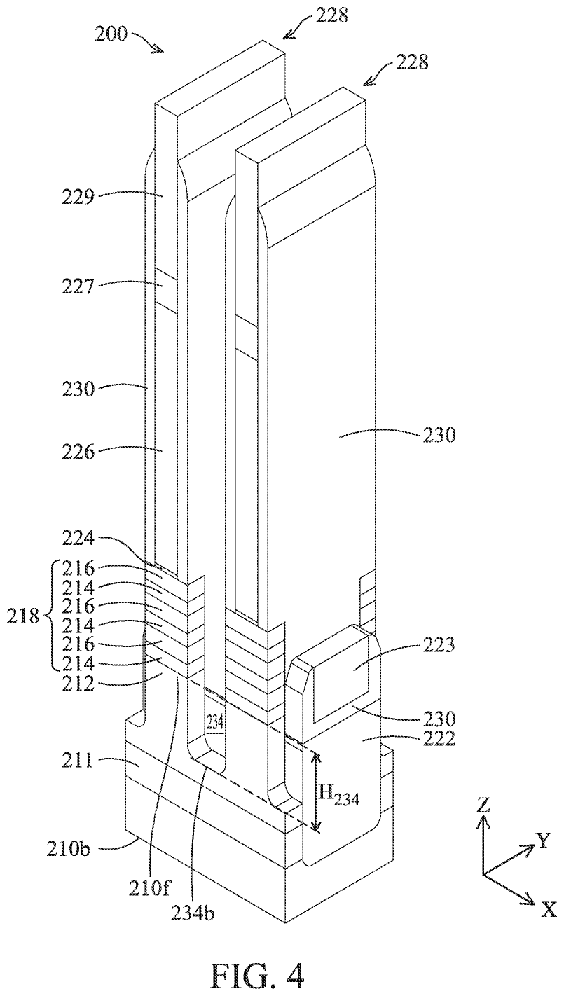

In operation 108, source/drain recesses 234 are formed by etching back the semiconductor fins 220, as shown in FIG. 4, which is a schematic perspective view of the semiconductor device 200. The semiconductor fins 220 on opposite sides of the sacrificial gate structure 228 are recess etched, forming the source/drain recesses 234 between the neighboring sacrificial gate structures 228. The first semiconductor layers 214 and the second semiconductor layers 216 in the semiconductor fins 220 are etched down on both sides of the sacrificial gate structures 228 using etching operations. In some embodiments, all layers in the semiconductor stack 218 of the semiconductor fins 220 and a portion of the well portions 212 of the semiconductor fins 220 are etched. In some embodiments, suitable dry etching and/or wet etching may be used to remove the first semiconductor layers 214, the second semiconductor layers 216, and the substrate 210. As shown in FIG. 4, the source/drain recesses 234 are formed on opposite sides of the sacrificial gate structures 228.

In some embodiments, the source/drain recesses 234 are shallow recesses compared to state-of-the-art technology. As discussed below, the shallow recesses avoid residual dielectric material during formation of inner spacers. In some embodiments, the source/drain recesses 234 are formed to a depth so that all the sacrificial semiconductor layers 214 in the semiconductor stack 218 is exposed. For example, a bottom surface 234b of the source/drain recesses 234 is below the top surface 210f of the substrate 210. As shown in FIG. 4, the bottom surface 234b of the source/drain recesses 234 is at a distance H₂₃₄ below the top surface 210f of the substrate 210. In some embodiments, the distance H₂₃₄ is in a range between about 2 nm and about 40 nm. In some embodiments, the distance H₂₃₄ is in a range between 1 time and 2.0 times of the thickness of the semiconductor layer 216.

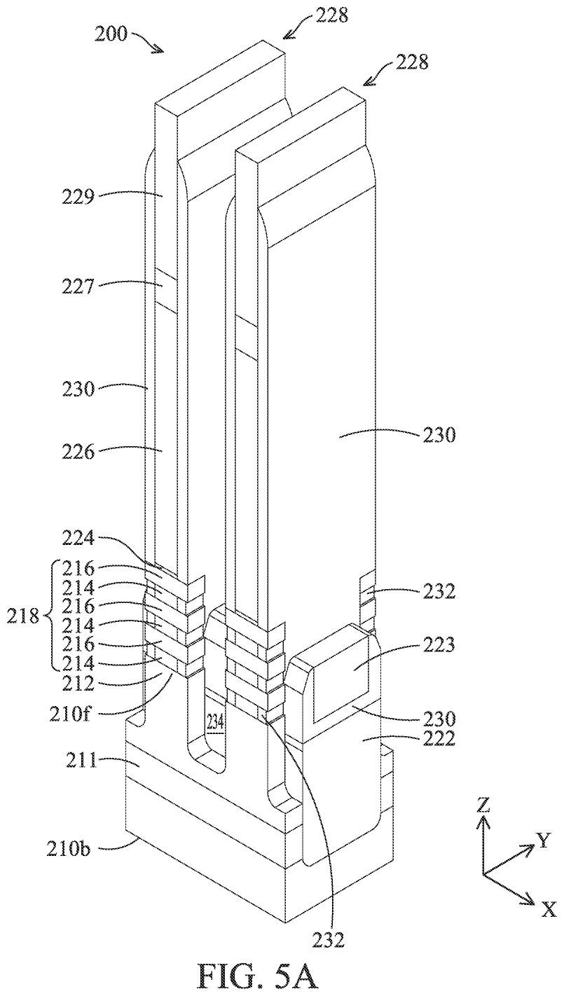

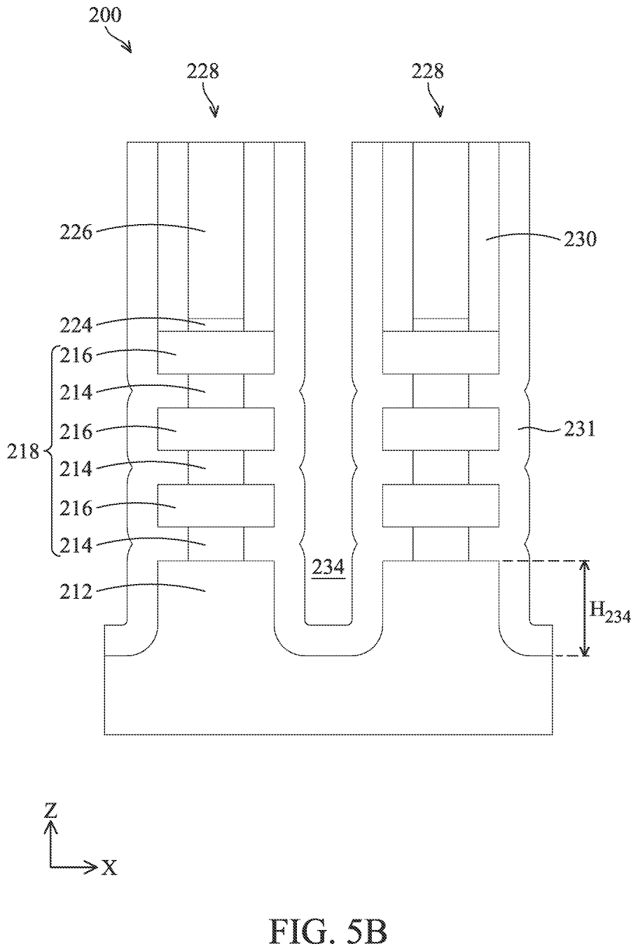

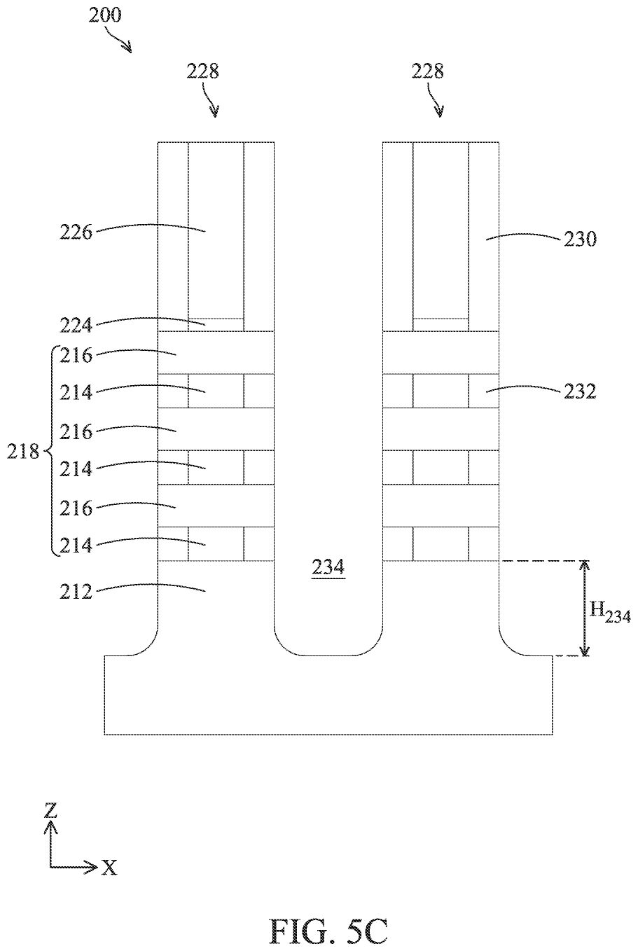

In operation 110, inner spacers 232 are formed on exposed ends of the first semiconductor layers 214 under the sacrificial gate structures 228, as shown in FIGS. 5A-5C. FIG. 5A is a schematic perspective view of the semiconductor device 200 after operation 110. FIG. 5B is a schematic cross sectional view of the semiconductor device 200 during an intermediate stage of forming the inner spacers 232. FIG. 5C is the schematic cross sectional view of the semiconductor device 200 after formation of the inner spacers 232.

The first semiconductor layers 214 exposed to the source/drain recesses 234 are first etched horizontally along the X direction to form spacer cavities. In some embodiments, the first semiconductor layers 214 can be selectively etched by using a wet etchant such as, but not limited to, ammonium hydroxide (NH₄OH), tetramethylammonium hydroxide (TMAH), ethylenediamine pyrocatechol (EDP), or potassium hydroxide (KOH) solutions. In some embodiments, the amount of etching of the first semiconductor layer 214 is in a range between about 3 nm and about 15 nm along the X direction.

After forming the spacer cavities at opposite ends of the first semiconductor layers 214, the inner spacers 232 can be formed in the spacer cavities by conformally deposit an insulating layer, as shown in FIG. 5B, and then partially remove an insulating layer, as shown in FIG. 5C. The insulating layer can be formed by ALD or any other suitable method. The subsequent etch process removes most of the insulating layer except inside the cavities, resulting in the inner spacers 232. The inner spacers 232 includes two or more segments, alternately stacked with the second semiconductor layers 216.

The inner spacers 232 may be formed from a single layer or multiple layers of dielectric material. In some embodiments, the inner spacers 232 may include one of silicon nitride (SiN) and silicon oxide (SiO₂), SiONC, or a combination thereof. The inner spacer 232 may have a thickness in a range from about 3 nm to about 15 nm along the X direction. Because the source/drain recesses 234 is relatively shallow compared to state-of-the-art technology, there is no residual of the inner spacer material on the bottom surface 234b after formation of the inner spacers 232.

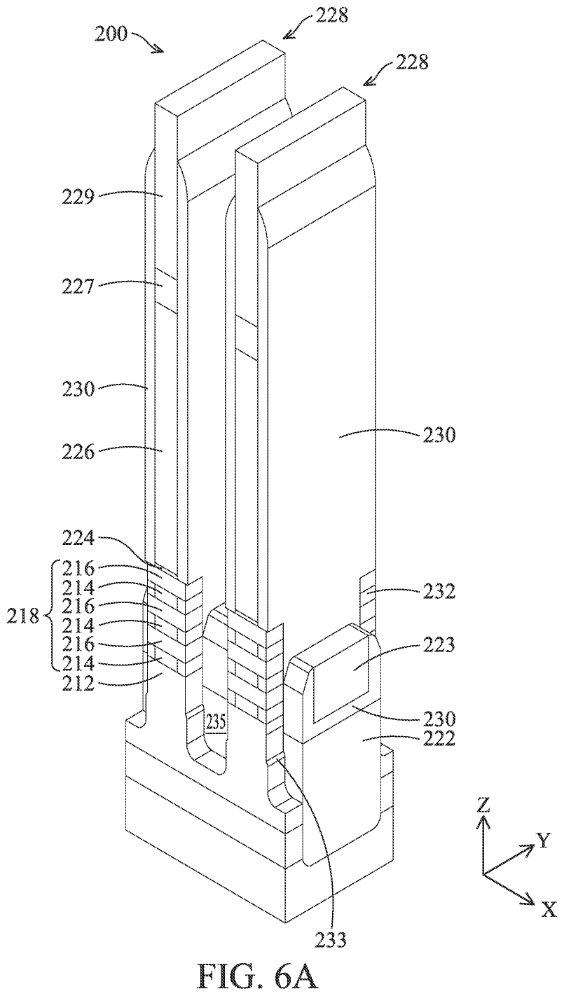

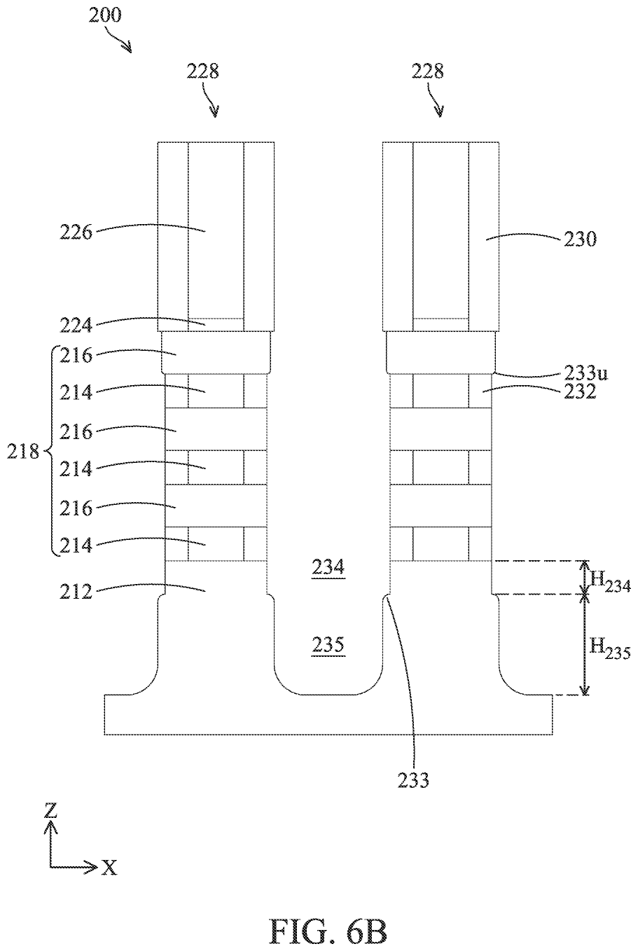

In operation 112, a second fin recess process is performed to form deep recesses 235 in the substrate 210, as shown in FIGS. 6A and 6B. FIG. 6A is a schematic perspective view of the semiconductor device 200. FIG. 6B is a schematic cross sectional view of the semiconductor device 200.

In some embodiments, the well portions 212 of the semiconductor fins 220 are further etched to form the deep recesses 235. In some embodiments, suitable dry etching and/or wet etching may be used to remove the substrate 210. As shown in FIGS. 6A-6B, the deep recesses 235 are formed from the bottom surface 234b of the source/drain recesses 234.

As a result of two different etching processes, a step 233 may be formed between the source/drain recess 234 and the corresponding deep recess 235, i.e., at the bottom surface 234b of the source/drain recess 234 and the entrance of the deep recess 235. In some embodiments, the deep recesses 235 are formed to a depth H₂₃₅. In some embodiments, the depth H₂₃₅ is in a range between about 5 nm and about 70 nm. In some embodiments, an upper step 233u may be formed between the topmost semiconductor layer 216 and the topmost inner spacers 232, as shown in FIG. 6B.

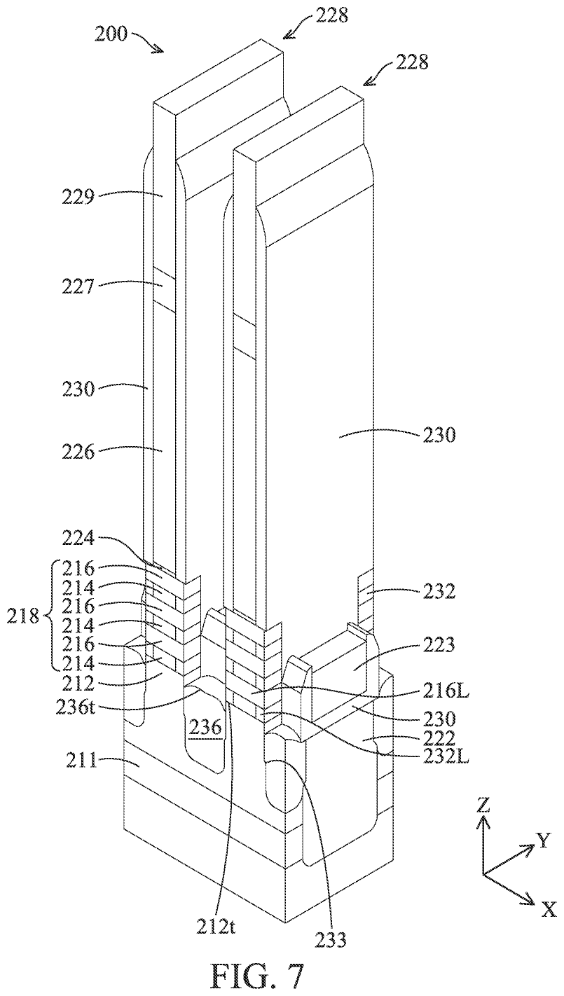

In operation 114, buried source/drain features 236 are formed in lower portions of the source/drain recesses 234, as shown in FIG. 7, which is a schematic perspective view of the semiconductor device 200. The buried source/drain features 236 fill the deep recesses 235 and lower portions of the source/drain recesses 234. In some embodiments, the buried source/drain features 236 are formed to a higher level then recessed to a level below the bottom most semiconductor layer 216L, or the bottom most channel region. In some embodiments, the buried source/drain features 236 fill the source/drain recesses 234 to a level below the bottom most inner spacers 232L. As shown in FIG. 7, a front surface 236t may be at a level below the bottom most inner spacers 232L.

The buried source/drain features 236 may be formed from a material to have etch selectivity relative to the material of the substrate 210, such as material in the well portion 212 of the semiconductor fin 220. In some embodiments, the buried source/drain features 236 may also have etch selectivity relative to the insulating material in the isolation layer 222. In some embodiments, the buried source/drain features 236 are formed from an undoped semiconductor material. In some embodiments, the buried source/drain features 236 are formed from a semiconductor material with a high etch selectivity relative to Si. For example, the buried source/drain features 236 are formed from SiGe or SiGeB. In some embodiments, the buried source/drain features 236 are formed from undoped SiGe. In some embodiments, the buried source/drain features 236 are formed from undoped SiGe or SiGeB including an atomic concentration of Ge in a range between about 10% and about 50%. Alternatively, the buried source/drain features 236 may include other materials with etch selectivity with the substrate 210, such as Ge, a compound semiconductor such as SiC, GeAs, GaP, InP, InAs, and/or InSb, an alloy semiconductor such as GaAsP, AlInAs, AlGaAs, InGaAs, GaInP, and/or GaInAsP, or combinations thereof. In some embodiments, the buried source/drain features 236 may be formed from a dielectric material, such as silicon oxide, silicon nitride, silicon oxynitride, silicon oxycarbide, silicon nitride carbide, metal oxide, such as aluminum oxide, hafnium oxide, or a combination thereof.

The buried source/drain features 236 may be formed by any suitable method, such as by CVD, CVD epitaxy, molecular beam epitaxy (MBE), or any suitable deposition technique.

As shown in FIG. 7, sidewalls of the buried source/drain features 236 have a step mirroring the step 233 between the source/drain recess 234 and the deep recesses 235.

During backside processes, the buried source/drain features 236 function as self-alignment features for forming contact holes to connect with source/drain regions. The material of the buried source/drain features 236 allows portions of the semiconductor fins 220 in the channel region and opposite source/drain region to be selectively removed. Additionally, the buried source/drain features 236 can be selectively removed without etching the dielectric materials in the isolation layer 222.

In FIG. 7, the buried source/drain features 236 are formed in all source/drain recesses 234. Alternatively, a patterning process may be performed to selectively deepen the source/drain recesses 234 and forming the deep recesses 235 and then form the buried source/drain features 236 in the selectively deepened source/drain recesses 234. For example, only source/drain regions with backside contacts would include the buried source/drain features 236.

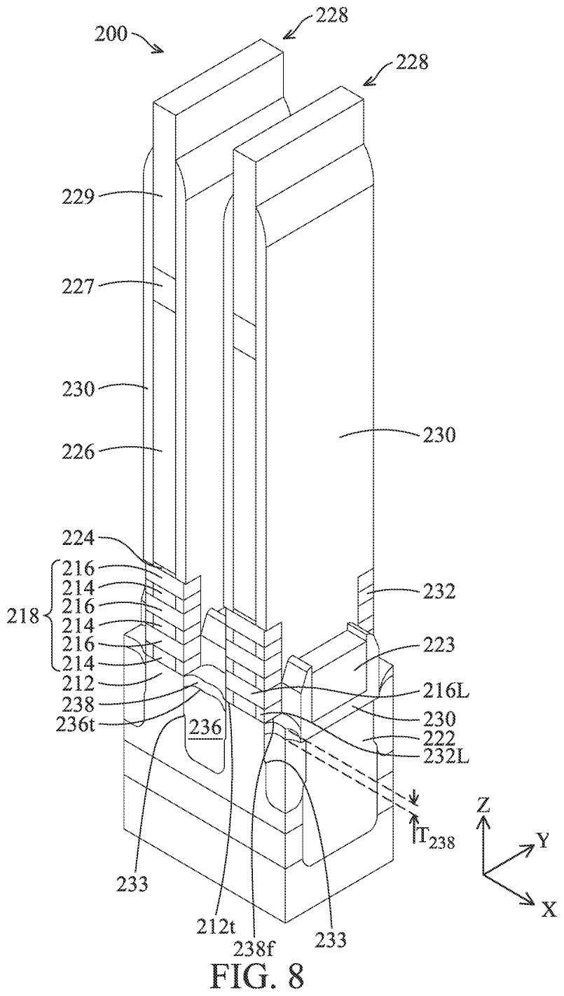

In operation 116, an optional semiconductor cap layer 238 is formed on the buried source/drain feature 236, as shown in FIG. 8, which is a perspective view of the semiconductor device 200. As shown in FIG. 8, the semiconductor cap layer 238 is formed on the front surface 236t of the buried source/drain features 236.

In some embodiments, the semiconductor cap layer 238 may include semiconductor material with etch selectivity from the buried source/drain features 236 so that the semiconductor cap layer 238 may function as an etch stop layer when removing the buried source/drain features 236 during backside processing. The semiconductor material in the semiconductor cap layer 238 also allows epitaxial growth of source/drain regions during subsequent processing, thereby reducing defects, such as voids in or around source/drain regions.

The semiconductor cap layer 238 may be formed by any suitable method, such as by ALD, CVD, or any suitable deposition technique. In some embodiments, the semiconductor cap layer 238 is formed by a molecular beam epitaxy (MBE) process, a metalorganic chemical vapor deposition (MOCVD) process, and/or other suitable epitaxial growth processes. In some embodiments, the semiconductor cap layer 238 may include the same material as the substrate 210. In some embodiments, the semiconductor cap layer 238 include an epitaxially grown silicon (Si) layer. Alternatively, the semiconductor cap layer 238 may include other materials having etch selectivity with the buried source/drain features 236, such as Si:B, SiN, SiCN, SiOCN, SiOC. The semiconductor cap layer 238 may include other materials compound semiconductor such as SiC, GeAs, GaP, InP, InAs, and/or InSb, an alloy semiconductor such as SiGe, GaAsP, AlInAs, AlGaAs, InGaAs, GaInP, and/or GaInAsP, or combinations thereof.

As shown in FIG. 8, the semiconductor cap layer 238 may have a thickness T₂₃₈ over the buried source/drain features 236. In some embodiments, the thickness T₂₃₈ is in a range between about 2 nm and about 5 nm. In some embodiments, a top surface 238f of the semiconductor cap layer 238 may intersect with the bottom most inner spacer 232L so that the semiconductor cap layer 238 covers the well portion 212 of the substrate 210 while keeping the bottom most semiconductor layer 216 exposed.

In some embodiments, the top surface 238f of the semiconductor cap layer 238 has a convex profile in the x-z plain. Particularly, the top surface 238f is higher along the z-direction near the center region and lower near the lower most inner spacers 232L. This is because the inner spacers 232 are formed from dielectric material and the semiconductor cap layer 238 can't grow from the inner spacers 232. As a result, the subsequently formed source/drain regions have a matching profile.

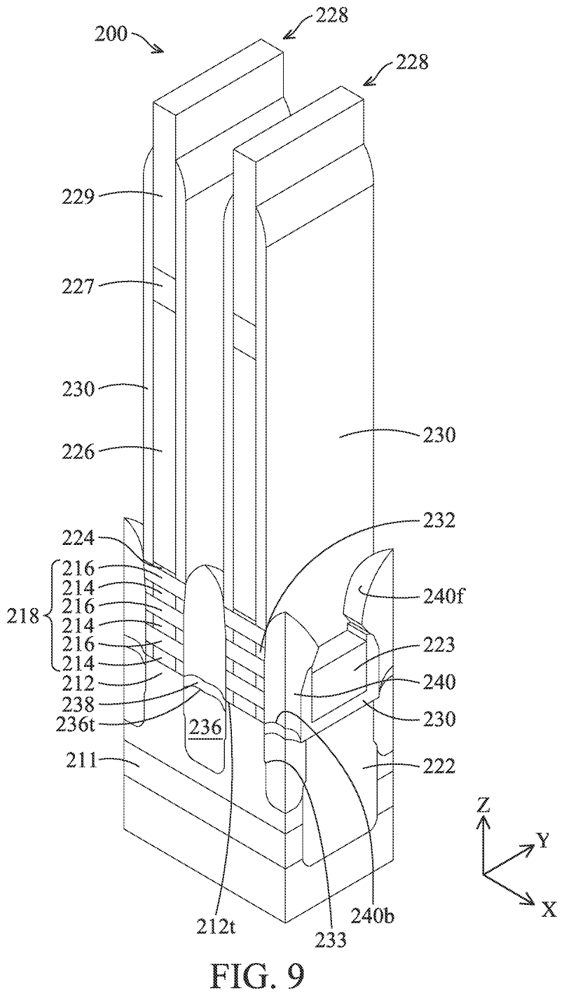

In operation 118, epitaxial source/drain regions 240 are formed in the source/drain recesses 234, as shown in FIG. 9, which is a schematic perspective view of the semiconductor device 200. In some embodiments, a preclean process may be performed prior to epitaxial growth of epitaxial source/drain regions 240 in the source/drain recesses 234. The epitaxial source/drain regions 240 are formed by an epitaxial growth method using CVD, ALD or molecular beam epitaxy (MBE). The epitaxial source/drain regions 240 may be for p-type devices or n-type devices. To form a n-type FET, the epitaxial source/drain regions 240 may include one or more layers of SiAs, SiP with a n-type dopant, such as As and P, in a concentration 5E19˜5E21/cm³. To form a p-type FET, the epitaxial source/drain regions 240 may include one or more layers of SiGe, SiGeB with Ge concentration in a range between about 10% and 50% and a p-type dopant, such as B, in a concentration 5E19˜5E21/cm³.

The epitaxial source/drain regions 240 are grown from exposed semiconductor surfaces, such as the second semiconductor layers 216 under the sacrificial gate structure 228 and the top surface 238f of the semiconductor cap layer 238. Because the epitaxial source/drain regions 240 grow from the top surface 238f of the semiconductor cap layer 238 in the bottom portion of the source/drain recesses 234, the epitaxial source/drain regions 240 may fill the source/drain recesses 234 without any voids. In some embodiments, the epitaxial source/drain regions 240 are grown pass the topmost semiconductor channel, i.e., the second semiconductor layer 216 under the sacrificial gate structure 228, to be in contact with the gate sidewall spacer layer 230. The first semiconductor layers 214 under the sacrificial gate structure 228 are separated from the epitaxial source/drain regions 240 by the inner spacers 232.

The epitaxial source/drain regions 240 may function as source regions and drain regions and are subsequently connected to power line or signal lines according to circuit design. For example, the epitaxial source/drain regions 240 that function as drain regions may be connected to signal lines; and the epitaxial source/drain regions 240 that function as source regions may be connected to a power rail. According to embodiments of the present disclosure, a portion of the epitaxial source/drain regions 240 may be connected to signal lines or power lines through connectors formed through the front surfaces 240f of the epitaxial source/drain regions 240 while another portion of the epitaxial source/drain regions 240 may be connected to signal lines or power lines through connectors formed through the back surfaces 240b of the epitaxial source/drain regions 240. In some embodiments, the back surfaces 240b of the source/drain regions 240 having a reversed smiley face profile.

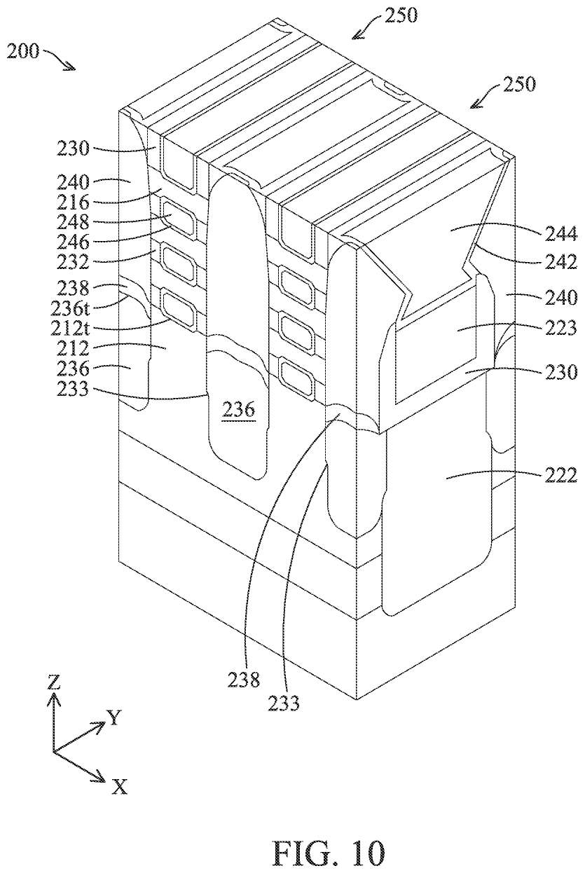

In operation 120, a contact etch stop layer (CESL) 242 and an interlayer dielectric (ILD) layer 244 are formed over the exposed surfaces as shown in FIG. 10, which is a schematic perspective view of the semiconductor device 200. The CESL 242 is formed on the epitaxial source/drain regions 240, the gate sidewall spacer layer 230. In some embodiments, the CESL 242 has a thickness in a range between about 1 nm and about 15 nm. The CESL 242 may include Si₃N₄, SiON, SiCN or any other suitable material, and may be formed by CVD, PVD, or ALD.

The interlayer dielectric (ILD) layer 244 is formed over the contract etch stop layer (CESL) 242. The materials for the ILD layer 244 include compounds comprising Si, O, C, and/or H, such as silicon oxide, SiCOH and SiOC. Organic materials, such as polymers, may be used for the ILD layer 244. After the ILD layer 244 is formed, a planarization operation, such as CMP, is performed to expose the sacrificial gate electrode layer 226 for subsequent removal of the sacrificial gate structures 228. The ILD layer 244 protects the epitaxial source/drain regions 240 during the removal of the sacrificial gate structures 228.

In operation 122, replacement gate structures 250 are formed in place of the sacrificial gate structures 228, as shown in FIG. 10. The sacrificial gate structures 228 are first removed. Particularly, the sacrificial gate electrode layer 226 and the sacrificial gate dielectric layer 224 are removed sequentially to form gate openings and expose the semiconductor stack 218. The sacrificial gate electrode layer 226 can be removed using plasma dry etching and/or wet etching. When the sacrificial gate electrode layer 226 is polysilicon and the ILD layer 244 is silicon oxide, a wet etchant such as a Tetramethylammonium hydroxide (TMAH) solution can be used to selectively remove the sacrificial gate electrode layer 226 without removing the dielectric materials of the ILD layer 244, the CESL 242, and the gate sidewall spacer layer 230. After removal of the sacrificial gate electrode layer 226, the sacrificial gate dielectric layer 224 is exposed. The sacrificial gate dielectric layer 224 can be removed using suitable etching methods, such as plasma dry etching and/or wet etching.

After removal of the sacrificial gate dielectric layer 224, the first semiconductor layers 214 and the second semiconductor layers 216 are exposed to the gate openings. The first semiconductor layers 214 are then selectively removed using an etchant with a higher etch rate with respect to the first semiconductor layers 214 than the etch rate with respect to the second semiconductor layers 216. When the first semiconductor layers 214 are Ge or SiGe and the second semiconductor layers 216 are Si, the first semiconductor layers 214 can be selectively removed using a wet etchant such as, but not limited to, ammonium hydroxide (NH₄OH), tetramethylammonium hydroxide (TMAH), ethylenediamine pyrocatechol (EDP), or potassium hydroxide (KOH) solution. After the first semiconductor layers 214 are removed, the second semiconductor layers 216 are exposed to the gate openings resulting in a semiconductor channel region including the second semiconductor layers 216 in connection to the epitaxial source/drain regions 240.

The replacement gate structures 250 are then formed around the channel region. A gate dielectric layer 246 is formed around each of the second semiconductor layers 216 and a gate electrode layer 248 is formed on the gate dielectric layer 246. The gate dielectric layer 246 and the gate electrode layer 248 may be referred to as a replacement gate structure 250.

The gate dielectric layer 246 may be formed by CVD, ALD or any suitable method. In one embodiment, the gate dielectric layer 246 is formed using a highly conformal deposition process such as ALD in order to ensure the formation of a gate dielectric layer 246 having a uniform thickness around each of the second semiconductor layers 216. In some embodiments, the thickness of the gate dielectric layer 246 is in a range between about 1 nm and about 6 nm.

The gate dielectric layer 246 includes one or more layers of a dielectric material, such as silicon oxide, silicon nitride, or high-k dielectric material, other suitable dielectric material, and/or combinations thereof. Examples of high-k dielectric material include HfO₂, HfSiO, HfSiON, HfTaO, HfTIO, HfZrO, zirconium oxide, aluminum oxide, titanium oxide, hafnium dioxide-alumina (HfO₂—Al₂O₃) alloy, other suitable high-k dielectric materials, and/or combinations thereof. In some embodiments, an interfacial layer (not shown) is formed between the second semiconductor layer 216 and the gate dielectric layer 246. In some embodiments, one or more work function adjustment layers (not shown) are interposed between the gate dielectric layer 246 and the gate electrode layer 248.

The gate electrode layer 248 is formed on the gate dielectric layer 246 to surround each of the second semiconductor layer 216 (i.e., each channel) and the gate dielectric layer 246. The gate electrode layer 248 includes one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. The gate electrode layer 248 may be formed by CVD, ALD, electro-plating, or other suitable method.

After the formation of the gate electrode layer 248, a planarization process, such as a CMP process, is performed to remove excess deposition of the gate electrode material and expose the top surface of the ILD layer 244.

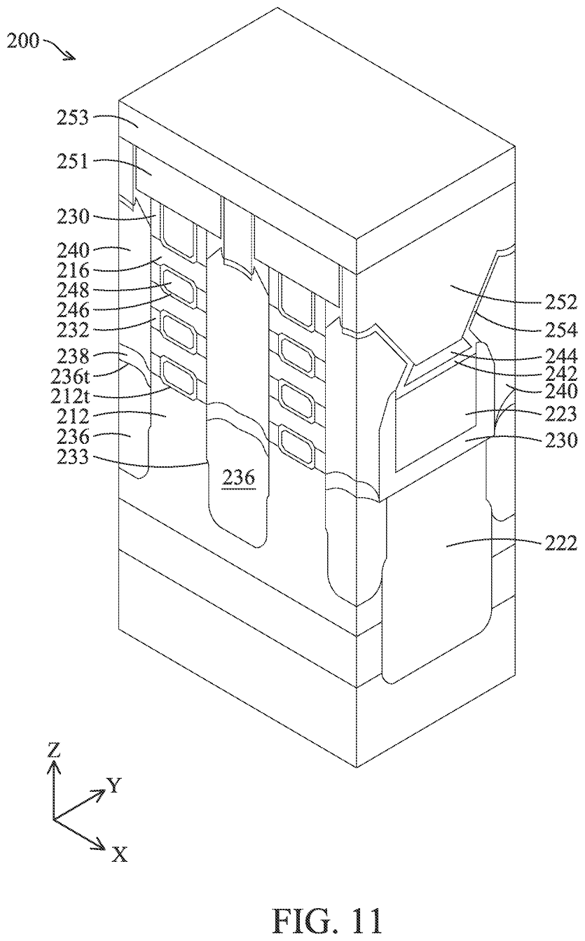

In operation 124, front side source/drain contacts 252 are formed in the ILD layer 244 through the front surface 240f of the epitaxial source/drain regions 240, as shown in FIG. 11, which is a schematic perspective view of the semiconductor device 200. Prior to forming the front side source/drain contacts 252, contact holes are formed in the ILD layer 244, the CESL 242, and a portion of the epitaxial source/drain regions 240. Suitable photolithographic and etching techniques are used to form the contact holes through various layers, including the ILD layer 244 and the CESL 242 to expose the epitaxial source/drain regions 240.

After the formation of the contact holes, a silicide layer 254 is selectively formed over an exposed surface of the epitaxial source/drain regions 240. The silicide layer 254 conductively couples the epitaxial source/drain regions 240 to the subsequently formed front side source/drain contacts 252. The silicide layer 254 may be formed by depositing a metal source layer to cover the epitaxial source/drain regions 240 and performing a rapid thermal annealing process. In some embodiments, the metal source layer includes a metal layer selected from W, Co, Ni, Ti, Mo, and Ta, or a metal nitride layer selected from tungsten nitride, cobalt nitride, nickel nitride, titanium nitride, molybdenum nitride, and tantalum nitride. After the formation of the metal source layer, a rapid thermal anneal process is performed, for example, a rapid anneal at a temperature between about 700° C. and about 900° C. During the rapid anneal process, the portion of the metal source layer over the epitaxial source/drain regions 240 reacts with silicon in the epitaxial source/drain regions 240 to form the silicide layer 254. Unreacted portion of the metal source layer is then removed. In some embodiments, the silicide layer 254 includes one or more of WSi, CoSi, NiSi, TiSi, MoSi, and TaSi. In some embodiments, the silicide layer 254 has a thickness in a range between about 4 nm and 10 nm, for example between 5 nm and 6 nm.

After the silicide layer 254 is formed, the front side source/drain contacts 252 are formed in the contact holes by CVD, ALD, electro-plating, or other suitable method. The front side source/drain contacts 252 may be in contact with the silicide layer 254. The front side source/drain contacts 252 may include one or more of Co, Ni, W, Ti, Ta, Cu, Al, TiN and TaN. In some embodiments, a barrier layer (not shown) may be formed on sidewalls of the contact holes prior to forming the front side source/drain contacts 252.

In some embodiments, the front side source/drain contacts 252 are selectively formed over some of the epitaxial source/drain regions 240 according to circuit design. The front side source/drain contacts 252 are formed over the epitaxial source/drain regions 240, which are designed to directly connect with the subsequent formed front side interconnect structure, but not over the epitaxial source/drain regions 240 which are designed to connect with signal lines or power lines front contacts formed on the backside. A suitable patterning process may be performed to selectively form the front side source/drain contacts 252. In other embodiments, the front side source/drain contacts 252 are formed over the epitaxial source/drain regions 240 for structural balance in the circuit design regardless of the subsequent design scheme. Some front side source/drain contacts 252 may be dummy contacts without connecting to the interconnect structure.

In some embodiments, gate contacts may be formed through self-aligned contact layer 251 to connect with the gate electrode layer 248. After formation of the front side source/drain contacts 252 and gate contacts are formed, a front side interconnect structure 253 (details not shown) is formed by a middle end of line process. The front side interconnect structure 253 includes multiple dielectric layers having metal lines and vias formed therein. The metal lines and vias in the front side interconnect structure may be formed of copper or copper alloys using one or more damascene processes. The front side interconnect structure may include multiple sets of inter-layer dielectric (ILD) layers and inter-metal dielectrics (IMDs) layers.

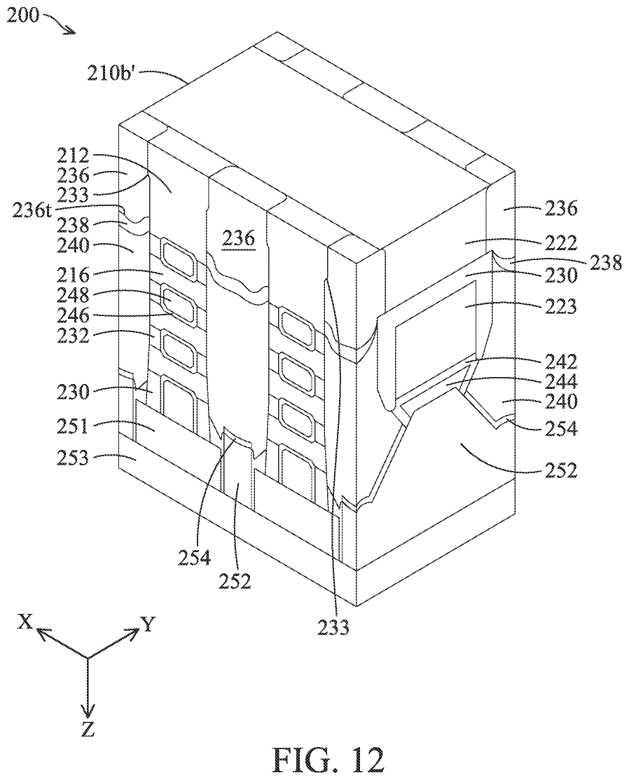

In operation 126, the semiconductor device 200 is flipped over and a back side thinning process is performed, as shown in FIG. 12, which is a schematic perspective view of the semiconductor device 200. In some embodiments, a carrier wafer (not shown) may be bond to a front side of the semiconductor device 200, and the substrate 210 is flipped over so that the backside of the substrate 210, i.e., the back surface 210b, is facing up for backside processing. A backside grinding is performed thin down the substrate 210. For example, the back side grinding, such as a CMP process, may be performed to expose the buried source/drain features 236. As shown in FIG. 12, after the thinning process, the semiconductor device 200 forms a planar back surface 210b′, which includes the isolation layer 222, the well portion 212, and the buried source/drain features 236.

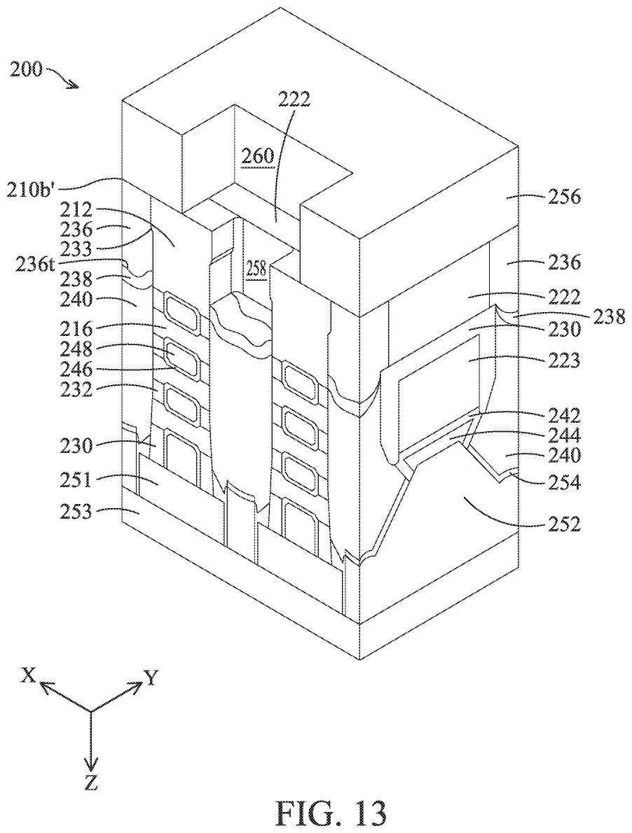

In operation 128, backside source/drain contact openings 258 are formed, as shown FIG. 13, which is a perspective view of the semiconductor device 200. In some embodiments, a mask layer 256 may be formed over the back surface 210b′. The mask layer 256 is patterned to form openings 260 over selected source/drain regions 240 according to the circuit design. A suitable patterning process is performed to form the openings 260 through the mask layer 256. In some embodiments, the source/drain regions 240 function as sources in the semiconductor device 200.

Each opening 260 exposes a buried source/drain feature 236. The openings 260 are larger than the buried source/drain feature 236, thus exposes the adjacent well portion 212 and isolation layer 222. Because the buried source/drain features 236 and the well portion 212 of the substrate 210 have high etching selectivity, the buried source/drain features 236 may be selectively removed from the well portion 212, therefore forming the backside source/drain contact openings 258 in alignment with the source/drain regions 240. In some embodiments, the source/drain contact openings 258 may be formed by an isotropic etch process. During removal of the buried source/drain features 236, the semiconductor cap layer 238 functions as an etch stop layer to protect the source/drain regions 240 from the etching chemistry.

After the buried source/drain features 236 are removed, an etch process may be performed to remove the semiconductor cap layer 238 and expose the source/drain region 240.

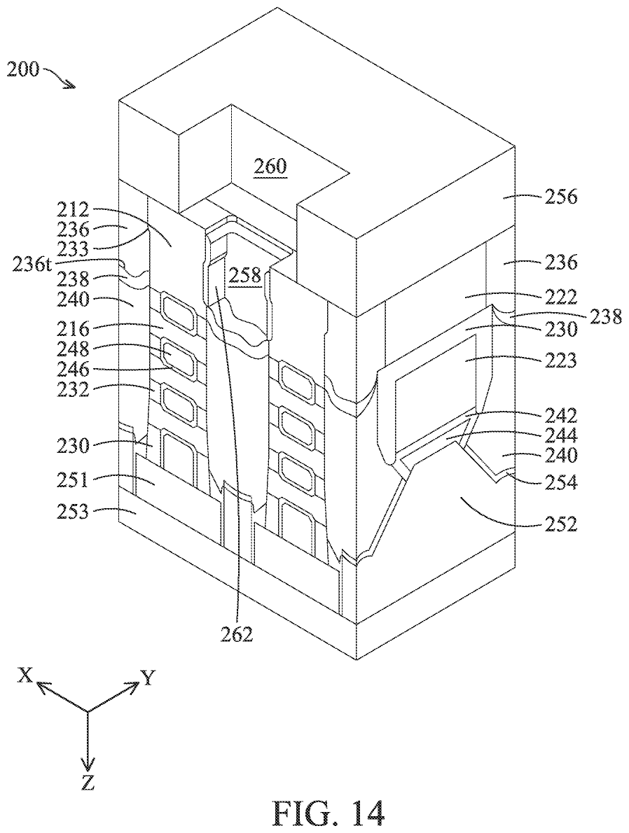

In operation 130, a backside source/drain contact liner 262 is formed on sidewalls of the source/drain contact openings 258, as shown in FIG. 14, which is a perspective view of the semiconductor device 200.

The backside source/drain contact liner 262 is intended to provide electrical isolation to the subsequently formed backside source/drain contacts from surrounding materials. The backside source/drain contact liner 262 may be formed by conformally forming an insulating material followed by anisotropic etch, such as a dry etch, to remove insulating material from horizontal surfaces. The backside source/drain contact liner 262 may have a thickness T₂₆₂ in a range between about 0 nm and about 8 nm. In some embodiments, the insulating material of the backside source/drain contact liner 262 may be a low-k dielectric material comprising Si, O, C, N. For example, the backside source/drain contact liner 262 may include SiO, SiN, SiON, SiOCN, SiCN, or combinations thereof.

As shown in FIG. 14, depending on the relative dimension of the backside source/drain contact liner 262 and the inner spacers 232, the backside/drain contact liner 262 may contact the bottom most inner spacers 232L.

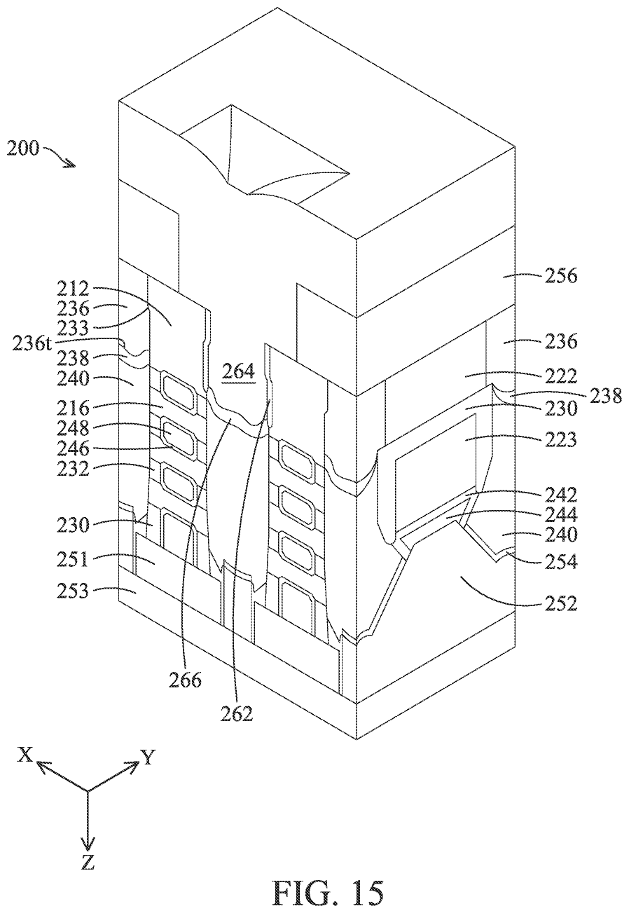

In operation 132, backside source/drain contacts 264 are formed in the backside source/drain contact openings 258, as shown in FIG. 15, which is a schematic perspective view of the semiconductor device 200. In some embodiments, a silicide layer 266 is first formed over the exposed source/drain region 240 prior to forming the backside source/drain contacts 264. In some embodiments, a preclean process may be performed using a plasma process. After preclean, a metal source layer may be formed on surfaces of the exposed source/drain region 240. The metal source layer may include W, Ru, Co, Cu, Ni, Ti, Mo, and Ta, or a metal nitride layer selected from tungsten nitride, cobalt nitride, nickel nitride, titanium nitride, molybdenum nitride, and tantalum nitride. The deposition of the metal source layer is followed by a rapid thermal annealing process at a temperature to form the silicide layer 266 on the exposed surface of the epitaxial source/drain regions 240. In some embodiments, the silicide layer 266 includes one or more of TiSi, CrSi, TaSi, MoSi, ZrSi, HfSi, ScSi, Ysi, HoSi, TbSI, GdSi, LuSi, DySi, ErSi, and YbSi. In some embodiments, the silicide layer 266 has a thickness in a range between about 1 nm and 10 nm.

The backside source/drain contacts 264 are formed in the backside source/drain contact openings 258. The backside source/drain contacts 264 may be formed by filling a conductive material in the source/drain contact openings 258. As shown in FIG. 15, the backside source/drain contacts 264 are in electrical connection with the source/drain region 240 via the silicide layer 266. The conductive material may be a metal, such as Ti, W, Ru, Mo, Co, Al, Cu, or compounds thereof. In some embodiments, the conductive material is filled in the contact holes by CVD, ALD, electro-plating, or other suitable method.

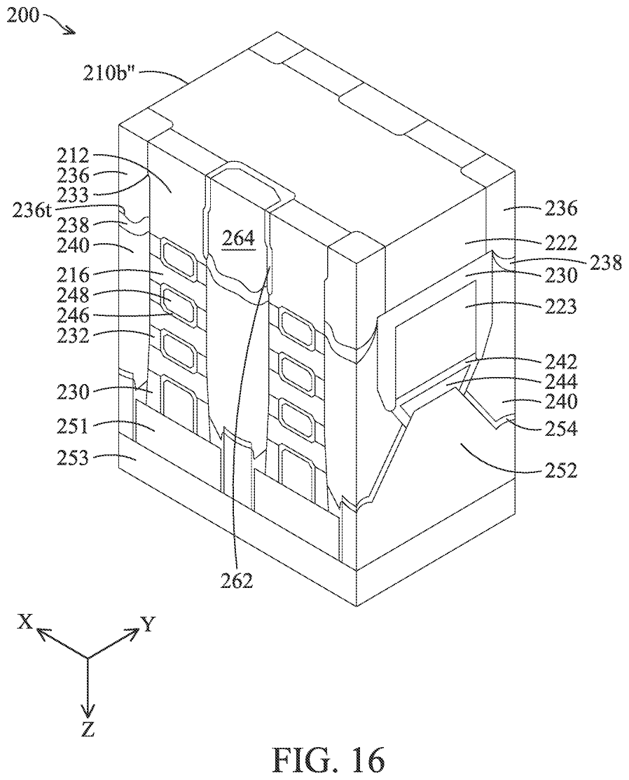

In operation 134, a planarization process is performed to remove excessive conductive material and expose the buried source/drain features 236, as shown in FIG. 16, which is a schematic perspective view of the semiconductor device 200. A planarization process, such as CMP, is performed to expose the isolation layer 222. The mask layer 256 and the excessive conductive material are removed from the CMP process resulting in a back surface 210b″. As shown in FIG. 15, the back surface 210b″ includes the isolation layer 222, the backside source/drain contacts 264, the backside source/drain contact liners 262, the buried source/drain features 236, and the well portions 212.

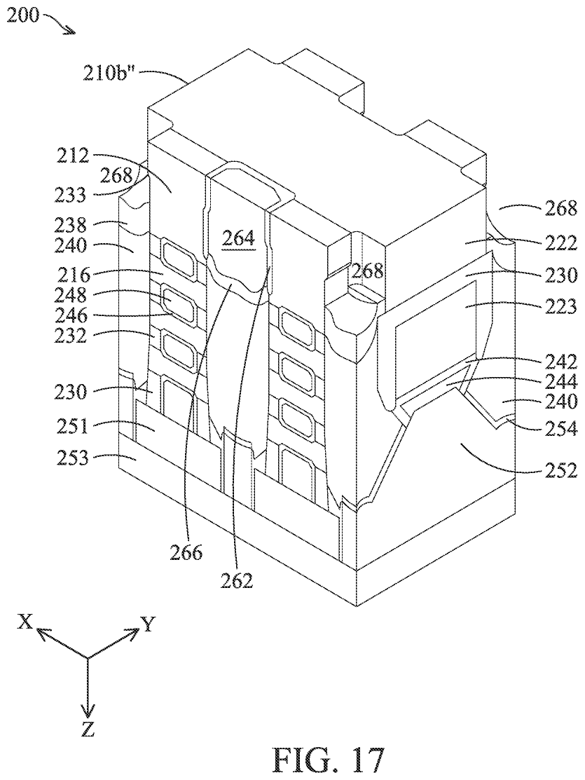

In operation 136, the buried source/drain features 236 exposed on the back surface 210b″ are removed, as shown in FIG. 17, which is a schematic perspective view of the semiconductor device 200. One or more etch processes may be performed to remove the buried source/drain features 236. Cavities 268 are formed over the semiconductor cap layer 238.

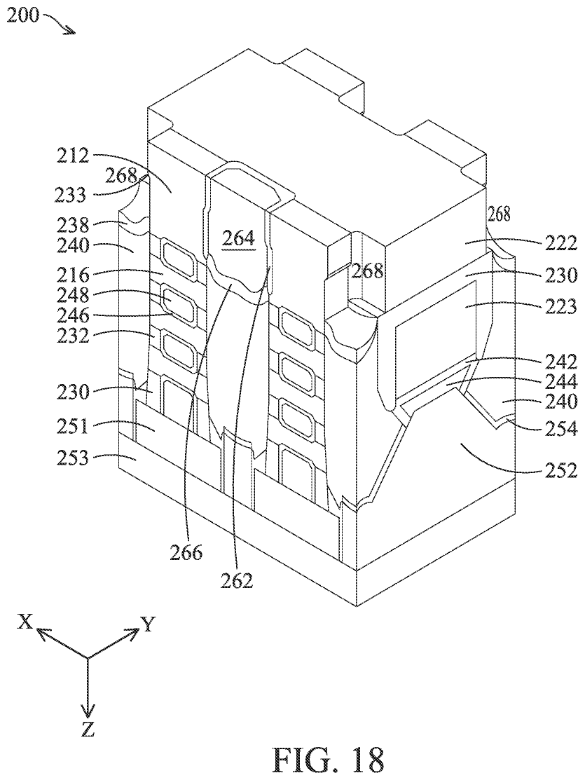

In operation 138, the semiconductor cap layer 238 is at least partially removed from the via cavities 268, as shown in FIG. 18, which is a schematic perspective view of the semiconductor device 200. The semiconductor cap layer 238 may be selectively removed from the well portion 212 of the substrate 210 and the epitaxial source/drain regions 240. As shown in FIG. 18, after removal of the semiconductor cap layer 238, the lower most inner spacers 232L and the gate sidewall spacer layer 230 may be exposed to the cavities 268.

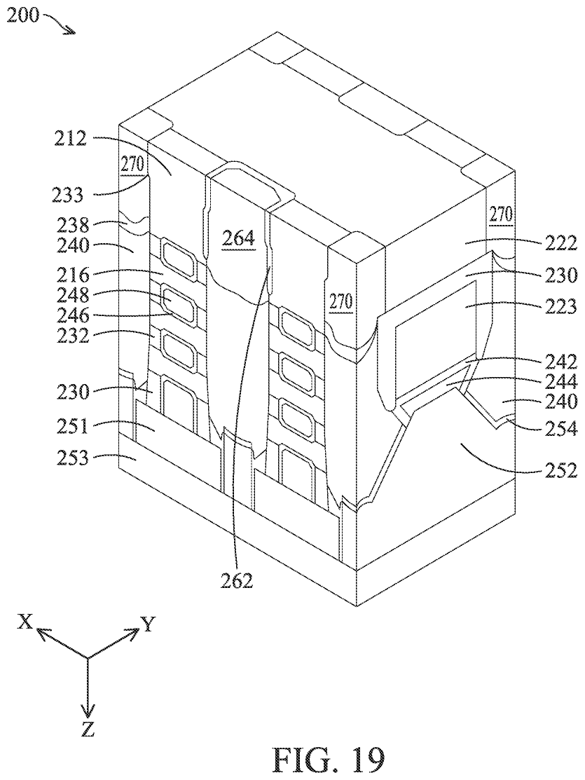

In operation 140, a dielectric fill layer 270 is deposited in the cavities 268 followed by a planarization process to expose the well portion 212 of the semiconductor fin 220, as shown in FIG. 19, which is a schematic perspective view of the semiconductor device 200. The dielectric fill layer 270 may be formed from any suitable dielectric material, such as a low-k dielectric material. In some embodiments, the dielectric fill layer 270 may be formed from SiO, SiOC, AlO, AlON, ZrO, HfO, TiO, ZrAlO, ZnO, TaO, LaO, YO, TaCN, SiN, SiOCN, SiCN, or a combination thereof. In some embodiments, the dielectric fill layer 270 includes silicon nitride. The dielectric fill layer 270 is in direct contact with the source/drain region 240 and the well portion 212 of the semiconductor fin 220 and provides isolation between the source/drain region 240 and the well portion 212 of the semiconductor fin 220.

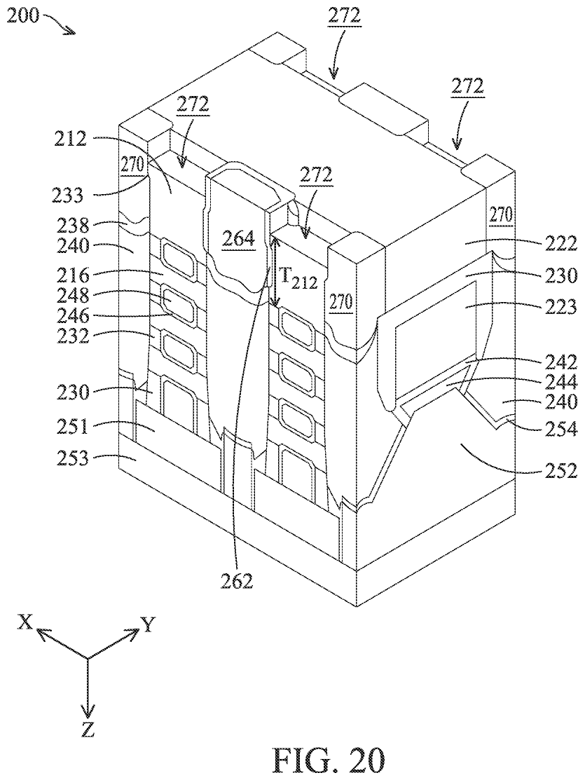

In operation 142, the well portions 212 of the semiconductor fins 220 are recessed to form recesses 272, as shown in FIG. 20, which is a schematic perspective view of the semiconductor device 200. In some embodiments, the well portions are recessed for a depth in a range between 5 nm and about 40 nm. The well portions 212 is removed to have the recesses 272 deep enough for a dielectric plug sufficient to provide isolation between the remaining semiconductor material and the subsequently formed conductive layer. In some embodiments, the remaining well portions 212, have a thickness T₂₁₂ in a range between about 2 nm and about 30 nm.

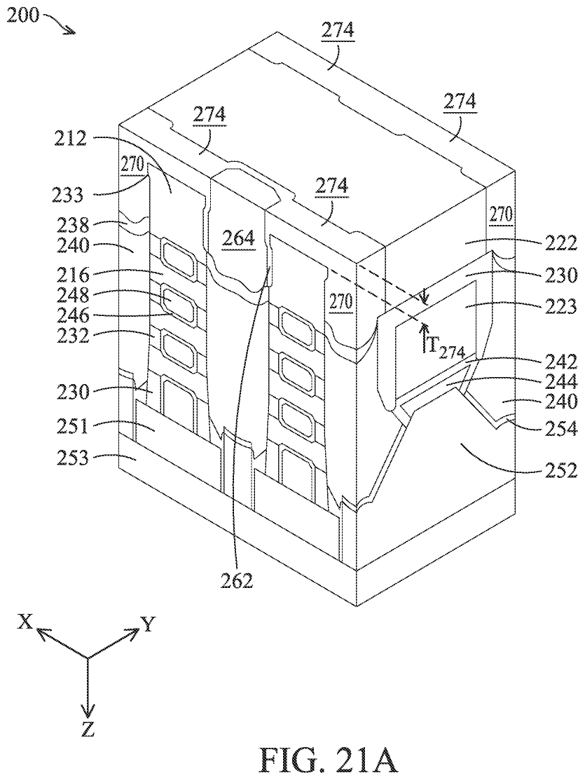

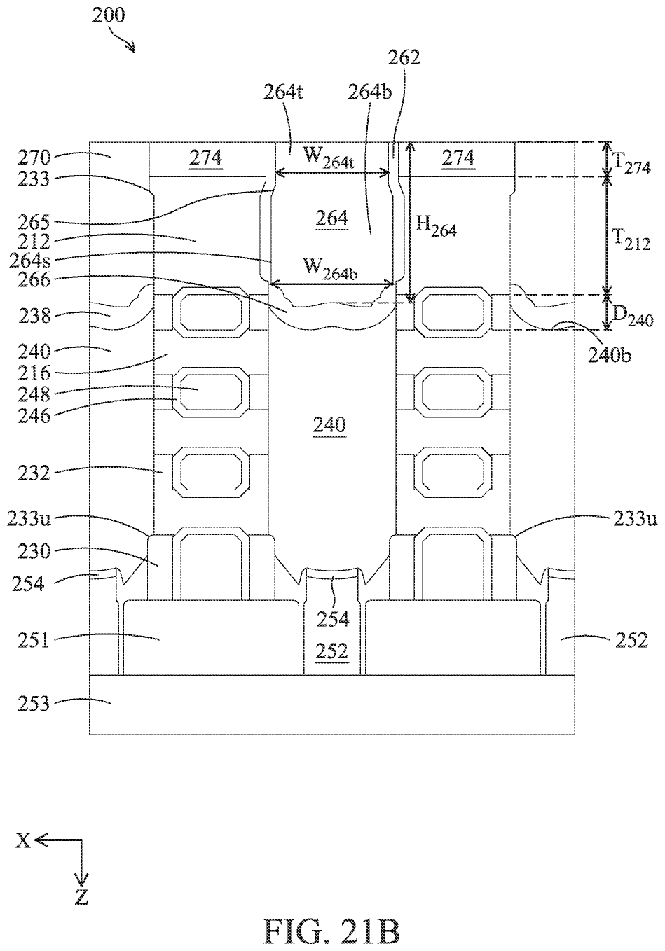

In operation 144, dielectric caps 274 are formed in the recesses 272, as shown in FIGS. 21A-21B. FIG. 21A is a schematic perspective view of the semiconductor device 200. FIG. 21B is a schematic cross-sectional view of the semiconductor device.

The dielectric caps 274 may be formed by filling the recesses 272 with suitable dielectric material followed by a CMP process. The dielectric caps 274 may have a thickness T₂₇₄ in a range between 5 nm and about 40 nm. The dielectric caps 274 may be formed from any suitable dielectric material, such as a low-k dielectric material. In some embodiments, the dielectric caps 274 may be formed from SiO, SiOC, AlO, AlON, ZrO, HfO, TiO, ZrAlO, ZnO, TaO, LaO, YO, TaCN, SiN, SiOCN, SiCN, or a combination thereof. In some embodiments, the dielectric caps 274 include silicon nitride. After operation 144, a backside interconnect structure may be formed to provide conductive paths to the backside source/drain contact 264. The dielectric caps 274 may provide isolation between the well portion 212 of the semiconductor fin 220 and conductive materials in subsequently formed backside interconnect structures. The dielectric caps 274 have a height H₂₇₄ along the z-direction. In some embodiments, the height H₂₇₄ is in a range between about 5 nm and about 40 nm.

The backside source/drain contacts 264 according to the present disclosure include unique structural features. As shown in FIG. 21B, the backside source/drain contacts 264 include a step 265 along sidewalls 264s facing the well portions 212 of the semiconductor fin 220. The step 265 reflects the step 233 formed at the entrance of the deep recess 235 during the front side processing. Because of the step 265, the backside source/drain contacts 264 have a wide portion 264b adjacent the source/drain regions 240 and a narrow portion 264t at a distal end away from the source/drain regions 240. In some embodiments, the wide portion 264b has a width W_{264b} along the x-direction in a range between about 10 nm and about 50 nm, and the narrow portion 264t has a width W₂₆₄ₜ in a range between about 8 nm and about 40 nm. In some embodiments, a ratio of width W₂₆₄ₜ over width W_{264b} is equal to or less than 1.0. The backside source/drain contacts 264 have a height H₂₆₄ along the z-direction. In some embodiments, the height H₂₆₄ is in a range between about 5 nm and about 70 nm. In some embodiments, the upper steps 233u remain in the semiconductor device 200 and are present in the cross-sections of the source/drain regions 240 as shown in FIG. 21B.

As previously discussed, the bottom surfaces 240b have a concaved profile because of the semiconductor cap layer 238. Even after the semiconductor cap layer 238 is removed, the bottom surface 240b retain the same concaved profile, or a smiley face profile shown in FIG. 21B. In FIG. 21B, the bottom surface 240b is lower at the center region and higher near the lower most inner spacers 232L. In some embodiments, the bottom surface 240b has a distance variation D₂₄₀ between the center and the edge regions. In some embodiments, the distance variation D₂₄₀ is in a range between about 1 nm and 5 nm.

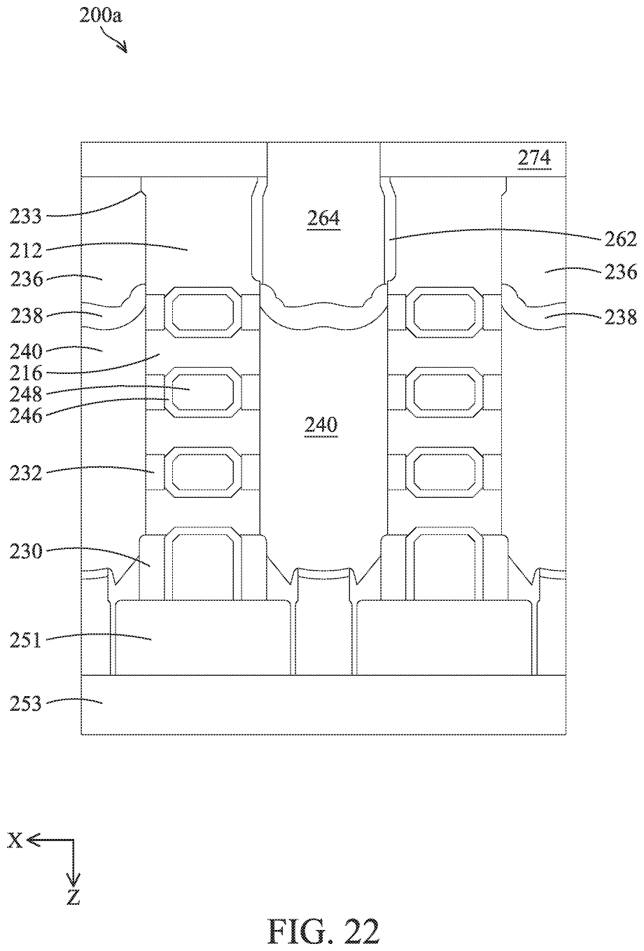

FIG. 22 schematically demonstrates a semiconductor device 200a according to embodiments of the present disclosure. The semiconductor device 200a is substantially similar to the semiconductor device 200 except that the buried source/drain features 236 on the drain side (or the side without backside source/drain contacts) only partially removed in the semiconductor device 200a. The semiconductor cap layer 238 remains between the source/drain region 240 and the partially removed buried source/drain features 236. In some embodiments, the semiconductor device 200a may be fabricated using the method 100 with operations 136, 138, and 140 omitted, and both the well portion 212 of the semiconductor fin 220 and the buried source/drain features 236 are recessed in operation 142.

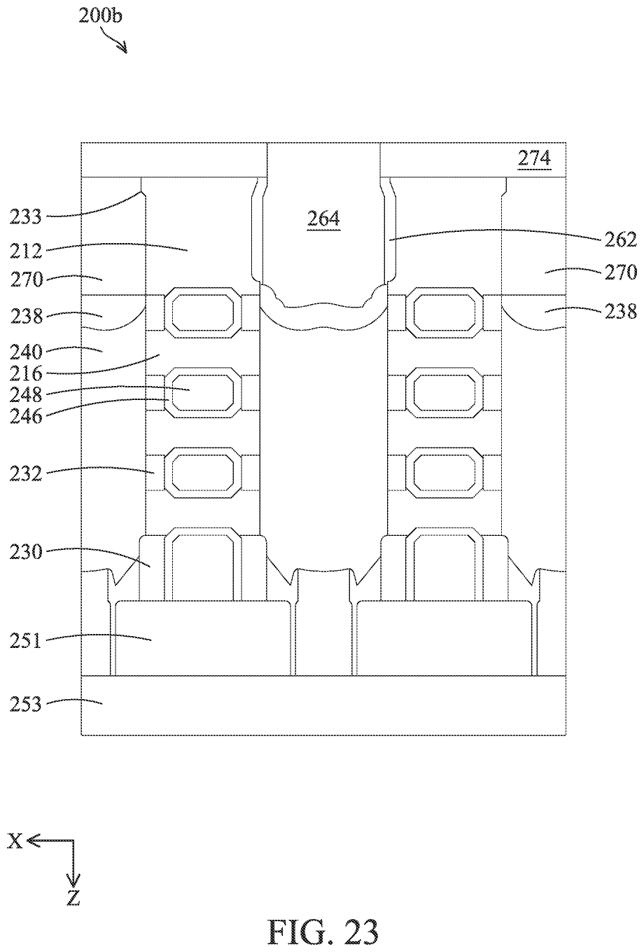

FIG. 23 schematically demonstrates a semiconductor device 200b according to embodiments of the present disclosure. The semiconductor device 200b is substantially similar to the semiconductor device 200 except that the semiconductor cap layer 238 is not removed in the semiconductor device 200b. The semiconductor cap layer 238 remains between the source/drain region 240 and the dielectric fill layer 270. In some embodiments, the semiconductor device 200b may be fabricated using the method 100 with operation 138 omitted.

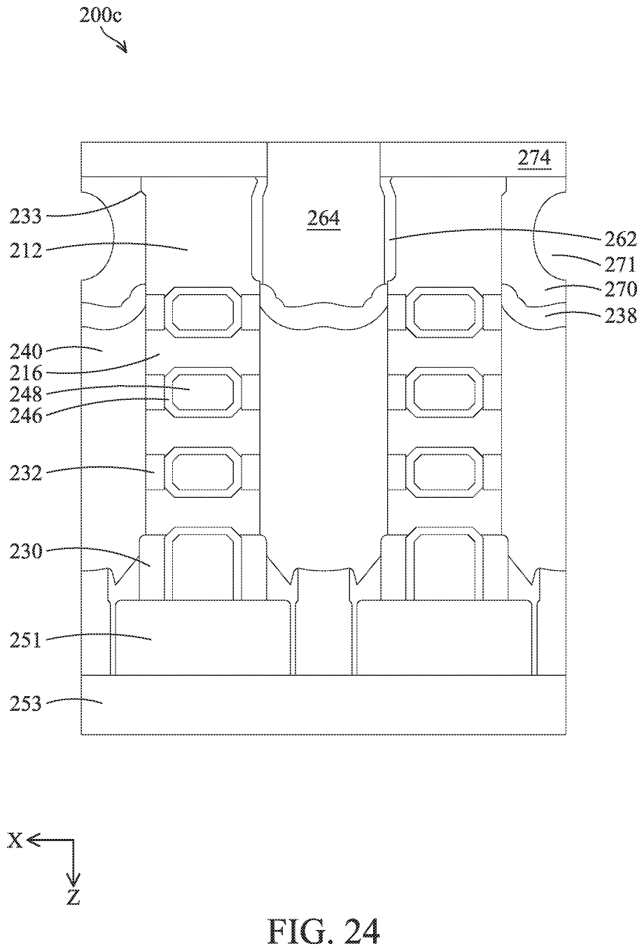

FIG. 24 schematically demonstrates a semiconductor device 200c according to embodiments of the present disclosure. The semiconductor device 200c is substantially similar to the semiconductor device 200 except that air gaps 271 are formed in the dielectric fill layer 270 in the semiconductor device 200c. In some embodiments, the semiconductor device 200c may be fabricated using the method 100 and process parameters in operation 140 are selected to generate air gaps 271 in the dielectric fill layer 270.

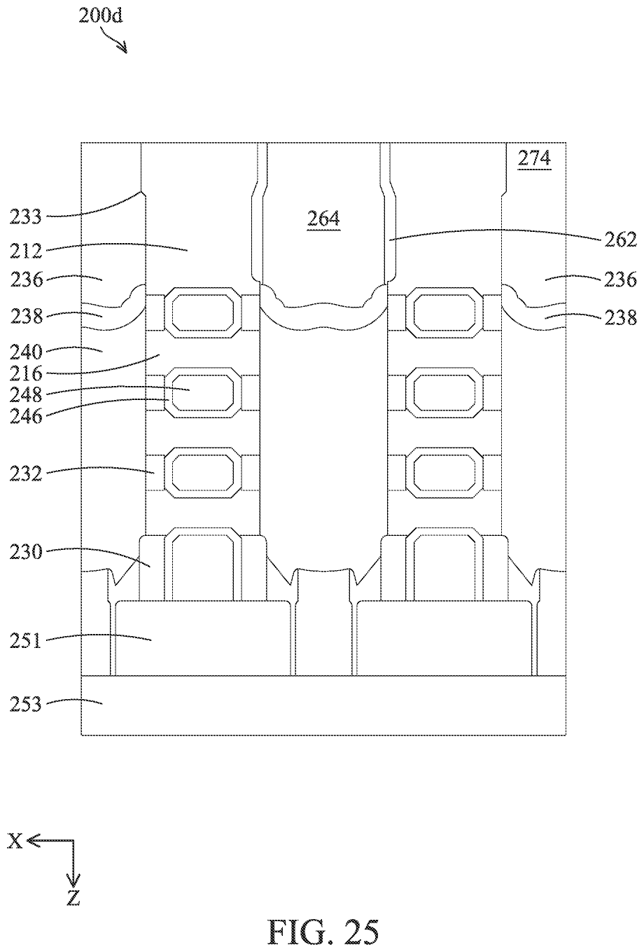

FIG. 25 schematically demonstrates a semiconductor device 200d according to embodiments of the present disclosure. The semiconductor device 200d is substantially similar to the semiconductor device 200a except that the dielectric cap 274 is omitted. In some embodiments, the semiconductor device 200d may be fabricated using the method 100 with operations 136, 138, 140, 142, and 144 omitted.

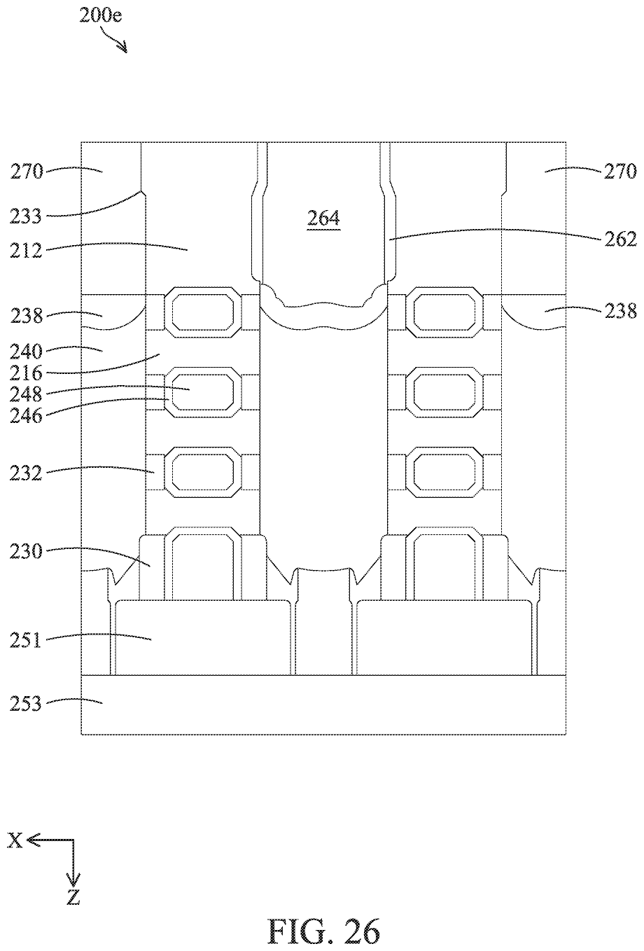

FIG. 26 schematically demonstrates a semiconductor device 200e according to embodiments of the present disclosure. The semiconductor device 200e is substantially similar to the semiconductor device 200b except that the dielectric cap 274 is omitted. In some embodiments, the semiconductor device 200e may be fabricated using the method 100 with operations 138, 142, and 144 omitted.

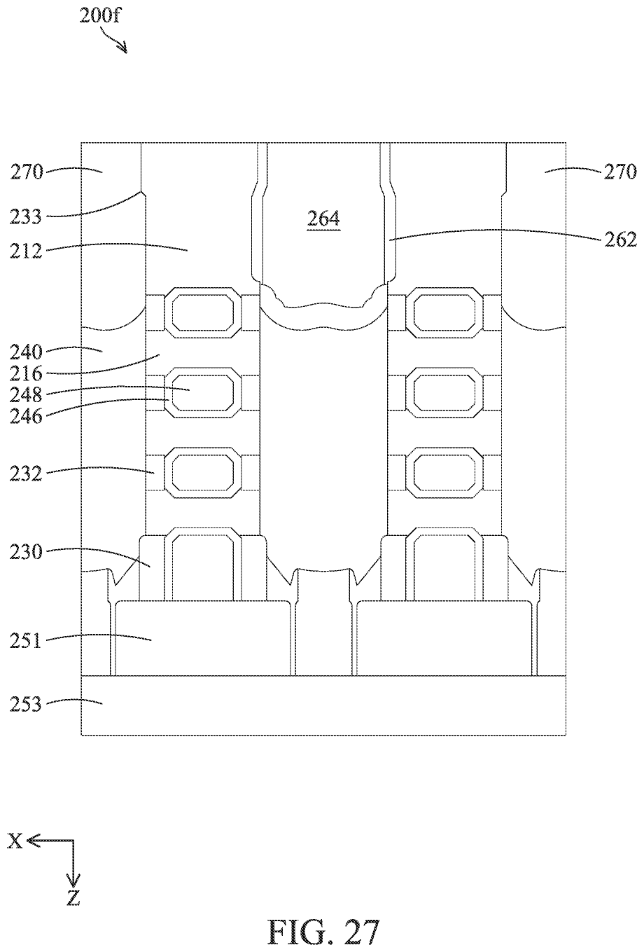

FIG. 27 schematically demonstrates a semiconductor device 200f according to embodiments of the present disclosure. The semiconductor device 200f is substantially similar to the semiconductor device 200 except that the dielectric cap 274 is omitted. In some embodiments, the semiconductor device 200f may be fabricated using the method 100 with operations 142, and 144 omitted.

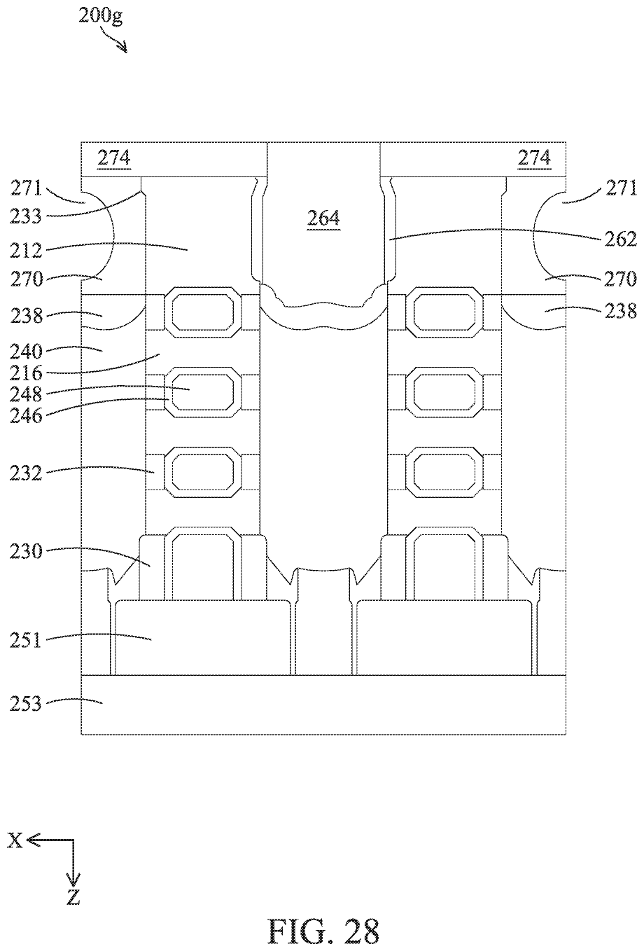

FIG. 28 schematically demonstrates a semiconductor device 200g according to embodiments of the present disclosure. The semiconductor device 200g is substantially similar to the semiconductor device 200c except that the dielectric cap 274 is omitted in the semiconductor device 200c but remains in the semiconductor device 200g. In some embodiments, the semiconductor device 200g may be fabricated using the method 100 with operations 142 and 144 omitted and process parameters in operation 140 are selected to generate air gaps 271 in the dielectric fill layer 270.

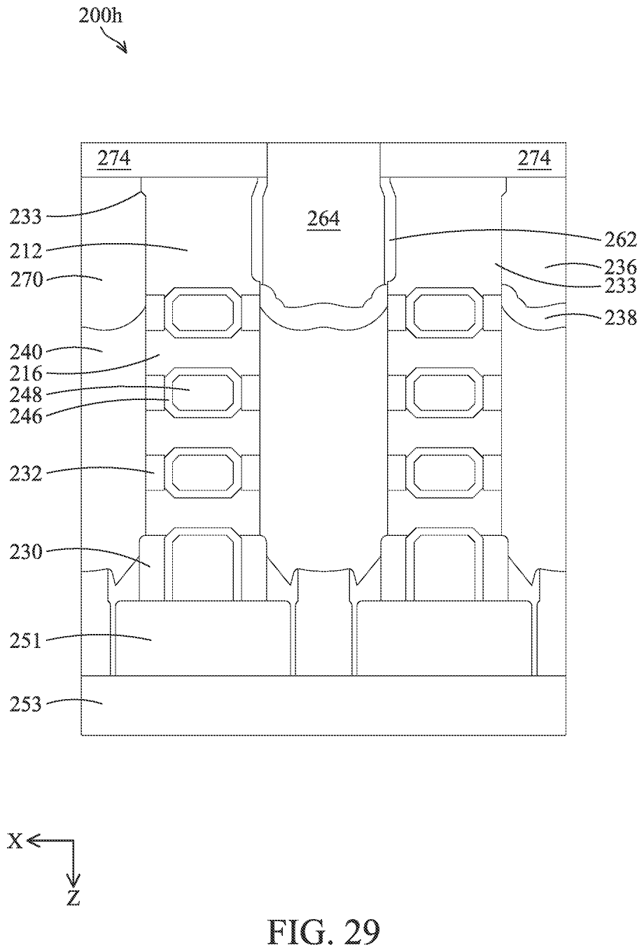

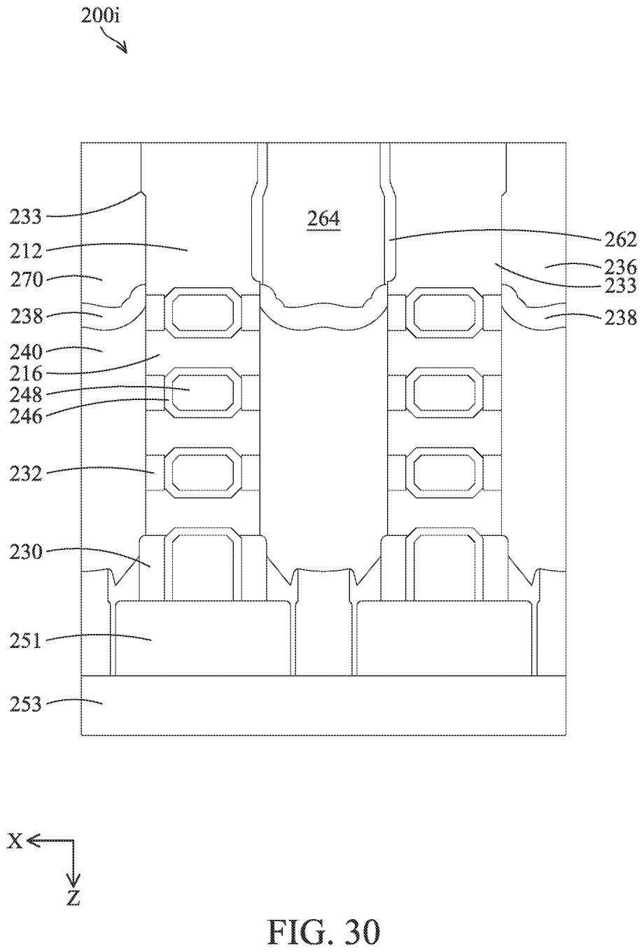

In the semiconductor devices 200 and 200a-200g, backside source/drain recess are performed on all drain regions with the buried source/drain features 236 removed. Alternatively, the backside source/drain recess may be performed partially so that only a portion of the buried source/drain features 236 are removed while a portion of the buried source/drain features 236 remain in the semiconductor device. FIGS. 29-30 schematically demonstrate embodiments with partially backside source/drain recess.

FIG. 29 schematically demonstrates a semiconductor device 200h according to embodiments of the present disclosure. The semiconductor device 200h is substantially similar to the semiconductor device 200 except that the buried source/drain features 236 remain on a portion of the source/drain regions 240.

FIG. 30 schematically demonstrates a semiconductor device 200i according to embodiments of the present disclosure. The semiconductor device 200i is substantially similar to the semiconductor device 200e except that the buried source/drain features 236 remain on a portion of the source/drain regions 240.

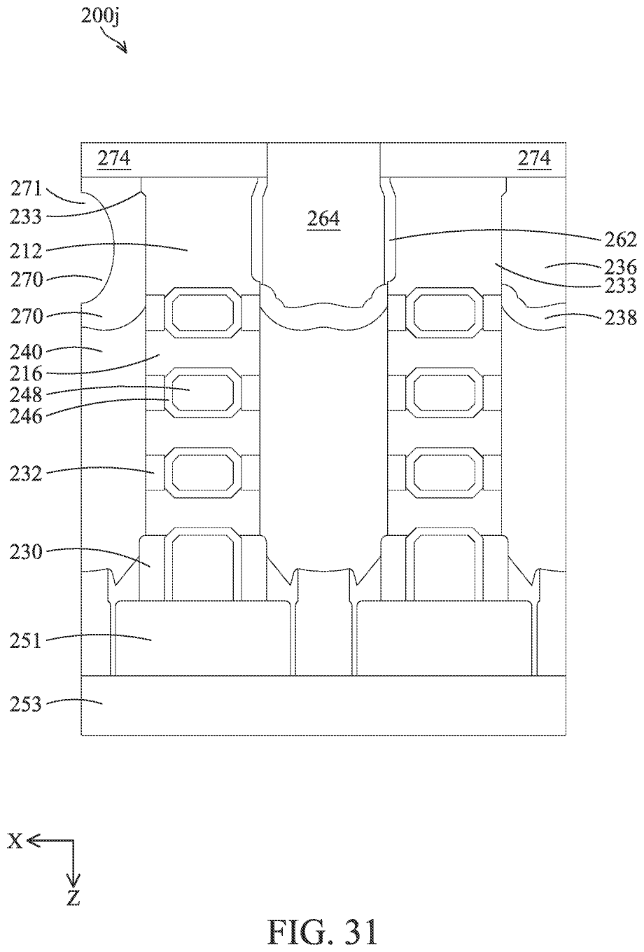

FIG. 31 schematically demonstrates a semiconductor device 200j according to embodiments of the present disclosure. The semiconductor device 200j is substantially similar to the semiconductor device 200g except that the buried source/drain features 236 remain on a portion of the source/drain regions 240.

Various embodiments or examples described herein offer multiple advantages over the state-of-art technology. Embodiments of the present disclosure provide a method of forming a semiconductor cap layer between a buried source/drain feature and a source/drain region. The buried source/drain feature and the semiconductor cap layer enable self-aligned backside source/drain contact and backside isolation. The semiconductor cap layer functions as an etch stop layer during backside contact formation while enabling source/drain region growth without fabrication penalty, such as voids in the source/drain regions.

It will be understood that not all advantages have been necessarily discussed herein, no particular advantage is required for all embodiments or examples, and other embodiments or examples may offer different advantages.

Some embodiments of the present provide a method. The method includes forming a semiconductor fin on a front side of a substrate; forming a sacrificial gate structure over the semiconductor fin; etching the semiconductor fin and the substrate to form first and second source/drain recesses on two sides of the sacrificial gate structure; depositing first and second buried source/drain features in the first and second source/drain recesses; forming first and second semiconductor cap layers over the first and second buried source/drain features; forming first and second source/drain regions over the first and second semiconductor cap layers; forming a replacement gate structure; thinning a backside of the substrate to expose the first and second buried source/drain features; removing the first buried source/drain feature and the first semiconductor cap layer to expose the first source/drain region; and forming a first backside source/drain contact on the first source/drain region.

Some embodiments of the present provide a method. The method includes forming a semiconductor fin on a front side of a substrate, wherein the semiconductor fin comprises two or more first semiconductor layers intervening with two or more second semiconductor layers; forming an isolation on the substrate and around a lower portion of the semiconductor fin; forming a sacrificial gate structure over the semiconductor fin; depositing a sidewall spacer layer; etching the semiconductor fin to a first depth; forming inner spacers on exposed ends of the second semiconductor layers; etching the semiconductor fin to a second depth, wherein the second depth is greater than the first depth; forming buried source/drain features on both sides of the semiconductor fin; and forming source/drain regions over the buried source/drain features.

Some embodiments provide a semiconductor device. The semiconductor device includes a first source/drain region; a second source/drain region; a semiconductor channel disposed between the first and second source/drain regions, wherein the semiconductor channel includes two or more semiconductor layers; a gate dielectric layer formed around the two or more semiconductor layers; a gate electrode layer disposed on the gate dielectric layer; a first front side source/drain contact disposed on a front surface of the first source/drain region; a first backside source/drain contact disposed on a back surface of the first source/drain region; and a second front side source/drain contact disposed on a front surface of the second source/drain region, wherein a back surface of the second source/drain region has a convex shape.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
forming a semiconductor fin on a front side of a substrate;
forming a sacrificial gate structure over the semiconductor fin;
etching the semiconductor fin and the substrate to form first and second source/drain recesses on two sides of the sacrificial gate structure;
depositing first and second buried source/drain features in the first and second source/drain recesses;
forming first and second semiconductor cap layers over the first and second buried source/drain features;
forming first and second source/drain regions over the first and second semiconductor cap layers;
forming a replacement gate structure;
thinning a backside of the substrate to expose the first and second buried source/drain features;
removing the first buried source/drain feature and the first semiconductor cap layer to expose the first source/drain region; and
forming a first backside source/drain contact on the first source/drain region.

2. The method of claim 1, further comprising:
prior to forming the first backside source/drain contact, forming a dielectric liner on sidewalls of an opening over the first source/drain region.

3. The method of claim 1, further comprising:
after forming the first backside source/drain contact, removing the second buried source/drain feature; and
depositing a dielectric fill layer in place of the second buried source/drain feature.

4. The method of claim 3, further comprising:
prior to depositing the dielectric fill layer, removing the second semiconductor cap layer to expose the second source/drain region.

5. The method of claim 3, wherein depositing the dielectric fill layer comprising forming an air gap in the dielectric fill layer.

6. The method of claim 3, further comprising:
etching a portion of the substrate to form a recess between the first backside source/drain contact and the dielectric fill layer; and
depositing a dielectric cap in the recess.

7. The method of claim 1, further comprising:
after forming the first backside source/drain contact, performing a planarization process to expose the substrate adjacent the first backside source/drain contact;
etching a portion of the substrate to form a recess in the substrate; and
depositing a dielectric cap in the recess.

8. The method of claim 7, further comprising:
etching a portion of the second buried source/drain feature, wherein the dielectric cap is deposited on the second buried source/drain feature and the substrate.

9. A method, comprising:
forming a semiconductor fin on a front side of a substrate, wherein the semiconductor fin comprises two or more first semiconductor layers intervening with two or more second semiconductor layers;
forming an isolation on the substrate and around a lower portion of the semiconductor fin;
forming a sacrificial gate structure over the semiconductor fin;
depositing a sidewall spacer layer;
etching the semiconductor fin to a first depth;
forming inner spacers on exposed ends of the second semiconductor layers;
etching the semiconductor fin to a second depth, wherein the second depth is greater than the first depth;
forming buried source/drain features on both sides of the semiconductor fin; and
forming source/drain regions over the buried source/drain features.

10. The method of claim 9, further comprising:
forming a semiconductor cap layer over the buried source/drain features, wherein the source/drain regions are formed on the semiconductor cap layer.

11. The method of claim 9, further comprising:
thinning a backside of the substrate to expose the buried source/drain features;
removing the buried source/drain features to expose the source/drain regions; and
forming backside source/drain contacts on the source/drain regions.

12. The method of claim 9, further comprising:
depositing a protective layer over the sidewall spacer layer; and
etching back the protective layer to expose the sidewall spacer layer on a top surface of the semiconductor fin.

13. The method of claim 9, wherein the buried source/drain features have a step at the first depth.

14. A semiconductor device, comprising:
a first source/drain region;
a second source/drain region;
a semiconductor channel disposed between the first and second source/drain regions, wherein the semiconductor channel includes two or more semiconductor layers;
a gate dielectric layer formed around the two or more semiconductor layers;
a gate electrode layer disposed on the gate dielectric layer;
a first front side source/drain contact disposed on a front surface of the first source/drain region;
a first backside source/drain contact disposed on a back surface of the first source/drain region; and
a second front side source/drain contact disposed on a front surface of the second source/drain region, wherein a back surface of the second source/drain region has a convex shape.

15. The semiconductor device of claim 14, further comprising a semiconductor cap layer, and the back surface of the second source/drain region is in contact with the semiconductor cap layer.

16. The semiconductor device of claim 15, further comprising a buried source/drain feature in contact with the semiconductor cap layer.

17. The semiconductor device of claim 15, further comprising a dielectric fill layer in contact with the semiconductor cap layer.

18. The semiconductive device of claim 14, further comprising a dielectric fill layer in contact with the back surface of the second source/drain region.

19. The semiconductive device of claim 14, wherein the first backside source/drain contact has a wide portion adjacent the first source/drain region, and a narrow portion disposed away from the first source/drain region.

20. The semiconductor device of claim 19, wherein the first backside source/drain contact includes a step formed along a sidewall, and the step is formed between the wide portion and the narrow portion.
